(19) United States
(12) Patent Application Publication
(10) Pub. No.: US 2026/0262261 A1
(43) Pub. Date: Sep. 3, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Fumito ISAKA, Zama (JP); Hitoshi KUNITAKE, Machida (JP)

(21) Appl. No.: 19/162,130

(22) PCT Filed: Mar. 11, 2024
(86) PCT No.: PCT/IB2024/052308

§ 371 Date: Sep. 4, 2025

(30) Foreign Application Priority Data
Mar. 17, 2023 (JP) 2023-042536

(51) Int. Cl. H10D 30/69; G11C 11/22; G11C 11/4096; G11C 14/00; G11C 16/04; G11C 16/10; G11C 16/26; H10B 12/00; H10B 41/27; H10B 41/35; H10B 41/41; H10B 43/27; H10B 43/35; H10B 43/40; H10B 51/20; H10B 51/30; H10B 51/40; H10B 53/20; H10B 53/30; H10B 53/40; H10D 30/67; H10D 64/68

(52) U.S. Cl. CPC H10D 30/701; G11C 11/223; G11C 11/2273; G11C 11/2275; G11C 11/4096; G11C 14/0018; G11C 14/0027; G11C 16/0483; H10B 41/27; H10B 41/35; H10B 41/41; H10B 43/27; H10B 43/35; H10B 43/40; H10B 51/20; H10B 51/30; H10B 51/40; H10D 30/6728; H10D 30/6731; H10D 30/6734; H10D 64/689; G11C 11/221; G11C 16/10; G11C 16/26; H10B 12/31; H10B 53/20; H10B 53/30; H10B 53/40

(57) ABSTRACT

A semiconductor device that includes different kinds of memory devices in the same chip is provided. Data transfer speed between two memory devices is improved. The semiconductor device includes a first layer, a second layer, and a third layer. The first layer includes a first storage device where a plurality of nonvolatile first storage elements are stacked in a thickness direction of the first layer. The second layer includes a second storage device that includes a plurality of second storage elements each including a transistor including an oxide semiconductor. The third layer includes a first driver circuit controlling operation of the first storage device and a second driver circuit controlling operation of the second storage device. The first layer, the second layer, and the third layer include a portion where they overlap each other.

### TECHNICAL FIELD

One embodiment of the present invention relates to a storage device. One embodiment of the present invention relates to a semiconductor device including a storage device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic appliance, a lighting device, an input device, an input/output device, a driving method thereof, and a manufacturing method thereof. A semiconductor device generally means a device that can function by utilizing semiconductor characteristics.

### BACKGROUND ART

Nonvolatile storage devices are incorporated in a variety of portable devices, including smartphones, tablet terminals, wristwatch-type terminals, wearable terminals for AR or VR, and the like. Until now, hard disk drives have been mainly used as nonvolatile storage devices; however, flash memories are widely used in the portable devices for reasons such as high impact resistance, capability of miniaturization, light weight, and no need for physical operation.

Meanwhile, a transistor including an oxide semiconductor in a channel formation region (also referred to as an oxide semiconductor transistor or an OS transistor)) is known. An OS transistor has a characteristic of extremely low drain current when the transistor is in an off state (such current is also referred to as off-state current). Patent Document 1 discloses a NAND-type storage device in which an OS transistor is employed.

### REFERENCE

### Patent Document

[Patent Document 1] PCT International Publication No. 2022/0068967

### SUMMARY OF THE INVENTION

### Problems to be Solved by the Invention

Data stored in a nonvolatile storage device used as a storage is often read to a higher-level memory device such as a DRAM and then transmitted to a processor. Therefore, it is preferable that data transfer speed between the nonvolatile storage device and the DRAM be as high as possible.

One object of one embodiment of the present invention is to provide a semiconductor device that includes different kinds of memory devices in the same chip. One object of one embodiment of the present invention is to improve data transfer speed between two memory devices. One object of one embodiment of the present invention is to provide a semiconductor device that includes two kinds of memory devices in the same chip and peripheral circuits.

One object of one embodiment of the present invention is to provide a highly reliable storage device or semiconductor device. One object of one embodiment of the present invention is to provide a storage device or a semiconductor device having a novel structure. One object of one embodiment of the present invention is to at least alleviate at least one of problems in the conventional art.

Note that the description of these objects does not preclude the presence of other objects. Note that one embodiment of the present invention does not need to achieve all these objects. Note that objects other than these can be derived from the description of the specification, the drawings, the claims, and the like.

Means for Solving the Problems One embodiment of the present invention is a semiconductor device including a first layer, a second layer, and a third layer. The first layer includes a first storage device where a plurality of nonvolatile first storage elements are stacked in a thickness direction of the first layer. The second layer includes a second storage device including a plurality of second storage elements. The second storage element includes a transistor including an oxide semiconductor. The third layer includes a first driver circuit controlling operation of the first storage device and a second driver circuit controlling operation of the second storage device. The first layer and the second layer, the second layer and the third layer, and the first layer and the third layer each include a portion where they overlap each other.

Alternatively, in the above, the first layer is preferably positioned over the third layer. In addition, in that case, the second layer is preferably positioned over the third layer.

Alternatively, in the above, the third layer is preferably positioned between the first layer and the second layer.

Alternatively, in the above, the first storage element preferably includes a first conductive layer, a first semiconductor layer, and a functional layer therebetween. In that case, the functional layer preferably includes a thin film exhibiting ferroelectricity.

Alternatively, in the above, the first storage element preferably includes a first conductive layer, a first semiconductor layer, and a functional layer therebetween. In that case, the functional layer preferably includes at least one of hafnium and zirconium. The functional layer preferably further contains one or more of scandium, yttrium, and an element belonging to lanthanoid.

Alternatively, in the above, the transistor preferably includes a gate insulating layer. In that case, the gate insulating layer preferably includes a thin film exhibiting ferroelectricity.

Alternatively, in the above, the second layer preferably includes an insulating layer. In addition, the transistor preferably includes a source electrode, a drain electrode, and a second semiconductor layer. In that case, each of the source electrode and the drain electrode is preferably in contact with the second semiconductor layer. Furthermore, one of the source electrode and the drain electrode is preferably positioned above the insulating layer, and the other of the source electrode and the drain electrode is preferably positioned below the insulating layer.

### Effect of the Invention

According to one embodiment of the present invention, a semiconductor device that includes different kinds of memory devices in the same chip can be provided. Alternatively, data transfer speed between two memory devices can be improved. Alternatively, a semiconductor device that includes two kinds of memory devices in the same chip and peripheral circuits can be provided.

According to one embodiment of the present invention, a highly reliable storage device or semiconductor device can be provided. Alternatively, a storage device or a semiconductor device having a novel structure can be provided. According to one embodiment of the present invention, at least one of problems in the conventional art can be at least alleviated.

Note that the description of these effects does not preclude the presence of other effects. Note that one embodiment of the present invention does not need to have all these effects. Note that effects other than these can be derived from the description of the specification, the drawings, the claims, and the like.

### BRIEF DESCRIPTION OF THE DRAWINGS

FIG. 1A and FIG. 1B are structure examples of a semiconductor device.

FIG. 2A to FIG. 2C are structure examples of the semiconductor device.

FIG. 3A to FIG. 3E are structure examples of a storage device.

FIG. 4 is a structure example of the semiconductor device.

FIG. 5 is a structure example of the semiconductor device.

FIG. 6 is a structure example of the storage device.

FIG. 7A to FIG. 7C are structure examples of the storage device.

FIG. 8 is a structure example of the semiconductor device.

FIG. 9A and FIG. 9B are structure examples of a storage device.

FIG. 10 is a diagram showing hysteresis characteristics.

FIG. 11A and FIG. 11B are structure examples of a storage device.

FIG. 12 is a structure example of the semiconductor device.

FIG. 13 is a structure example of the semiconductor device.

FIG. 14 is a structure example of the semiconductor device.

FIG. 15 is a structure example of the semiconductor device.

FIG. 16 is a structure example of the semiconductor device.

FIG. 17 is a structure example of the semiconductor device.

FIG. 18 is a structure example of the semiconductor device.

FIG. 19 is a structure example of the semiconductor device.

FIG. 20 is a block diagram illustrating a structure example of a semiconductor device.

FIG. 21A to FIG. 21H are diagrams each illustrating a circuit structure example of a memory cell.

FIG. 22A and FIG. 22B are perspective views each illustrating a structure example of the semiconductor device.

FIG. 23 is a block diagram illustrating a CPU.

FIG. 24A and FIG. 24B are perspective views of a semiconductor device.

FIG. 25A and FIG. 25B are perspective views of semiconductor devices.

FIG. 26A and FIG. 26B are diagrams showing hierarchies of a variety of storage devices.

FIG. 27A to FIG. 27J are diagrams illustrating examples of electronic devices.

FIG. 28A to FIG. 28E are diagrams illustrating examples of electronic devices.

FIG. 29A to FIG. 29C are diagrams illustrating examples of electronic devices.

FIG. 30 is a diagram illustrating an example of space equipment.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of the embodiments below.

Note that in structures of the invention described below, the same portions or portions having similar functions are denoted by the same reference numerals in different drawings, and the description thereof is not repeated. In addition, the same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

### Embodiment 1

In this embodiment, a semiconductor device and a storage device according to one embodiment of the present invention will be described.

One embodiment of the present invention is a semiconductor device that includes two kinds of storage devices (memory devices). The semiconductor device has a structure where a first layer including a memory cell (also referred to as a storage element) of a first storage device, a second layer including a memory cell of a second storage device, and a third layer including a first driver circuit that controls operation of the first storage device and a second driver circuit that controls operation of the second storage device are stacked. Accordingly, wiring length between the first storage device and the second storage device can be shortened, so that the data amount per unit time in data exchange between these storage devices can be increased.

The first storage device preferably includes a nonvolatile storage element functioning as a storage. In addition, the first storage device preferably has larger data capacity than the second storage device. For example, it is preferable to use a large-capacity storage device with what is called a 3D structure where storage elements are arranged in an in-plane direction of the first layer and also stacked in a thickness direction. As a more specific example, it is preferable to use a 3D-NAND-type storage device that includes a memory string extending in a normal direction with respect to a formation surface.

It is preferable to use a nonvolatile storage device utilizing a ferroelectric as the first storage device. Accordingly, a storage device that has high reliability and low power consumption compared to what is called a charge trapping-type storage element can be achieved.

The second storage device is preferably a storage device having higher access speed than the first storage device. The second storage device may be a volatile storage device, which loses information when the supply of power is stopped. As a more specific example, a DRAM (Dynamic Random Access Memory) can be used.

Alternatively, it is further preferable to use a storage device where a transistor using an oxide semiconductor in a channel formation region (an OS transistor) is used in a memory cell as the second storage device. The OS transistor has a feature of extremely low leakage current in an off state; thus, the storage device using the OS transistor can retain data for a longer period than a DRAM, which can reduce power consumption. In addition, the oxide semiconductor can be formed as a thin film, and the OS transistor can be manufactured regardless of a formation surface. For example, there is an advantage that a circuit including an OS transistor can be stacked directly on a semiconductor circuit or the like including single crystal silicon.

More specific examples are described below with reference to drawings.

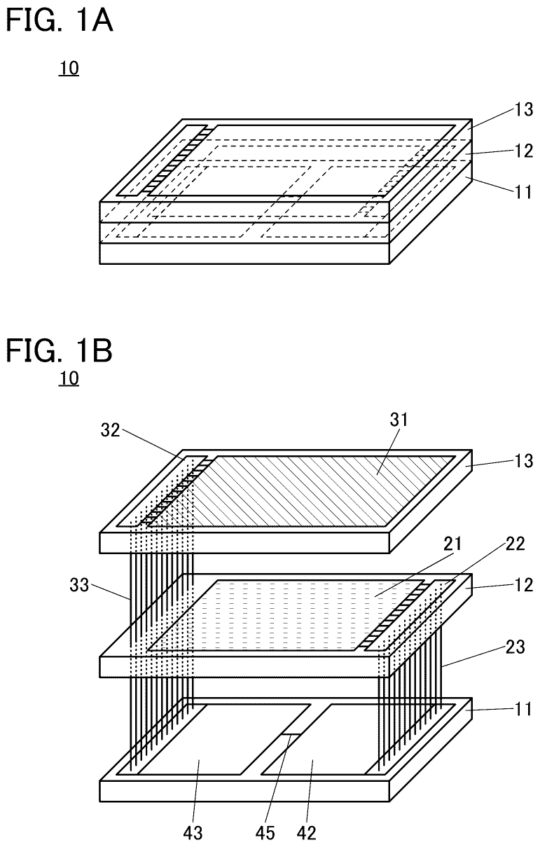

FIG. 1A illustrates a semiconductor device 10 according to one embodiment of the present invention. The semiconductor device 10 has a structure where a layer 11, a layer 12, and a layer 13 are stacked. The layer 12 is sandwiched between the layer 11 and the layer 13.

FIG. 1B is a diagram explicitly illustrating the semiconductor device 10 layer by layer. The layer 13 includes a storage device 31 including a plurality of storage elements (memory cells) and a connection portion 32. The layer 12 includes a storage device 21 including a plurality of storage elements and a terminal portion 22. The layer 11 includes a driver circuit 43 that controls operation of the storage device 31 and a driver circuit 42 that controls operation of the storage device 21.

For the layer 12, a storage device that has larger data capacity than the layer 13 and includes a nonvolatile storage element can be used. On the other hand, for the layer 13, a storage device that has higher access speed than the layer 12 can be used.

The driver circuit 43 and the driver circuit 42 are connected through a wiring 45, and data exchange therebetween can be executed. For example, data can be transferred from the storage device 31 to the storage device 21 through the driver circuit 43, the wiring 45, and the driver circuit 42. On the contrary, data can be transferred from the storage device 21 to the storage device 31.

A plurality of plugs 23 that connect a circuit provided in the layer 11 (here, the driver circuit 42) to the terminal portion 22 of the layer 12 are provided in the semiconductor device 10. Furthermore, a plurality of plugs 33 that connect a circuit provided in the layer 11 (here, the driver circuit 43) to the connection portion 32 of the layer 13 are provided in the semiconductor device 10. The plugs 33 partly penetrate the layer 12.

With such a structure, an occupied area can be dramatically reduced compared to the case where two storage devices and two driver circuits are placed side by side. In addition, wiring length between the storage device and the driver circuit can be reduced compared to the case where the storage device and the driver circuit are placed side by side, so that a wiring load is reduced. Consequently, in each of the storage devices, data writing and reading speed can be improved.

In addition, in FIG. 1B and the like, a region in the layer 13 that overlaps the terminal portion 22 can also function as part of the storage device 31. In other words, the storage device 31 can include a portion that overlaps the terminal portion 22 in the layer 12. Efficient use of such a space is preferable because the data capacity of the storage device 31 can be increased.

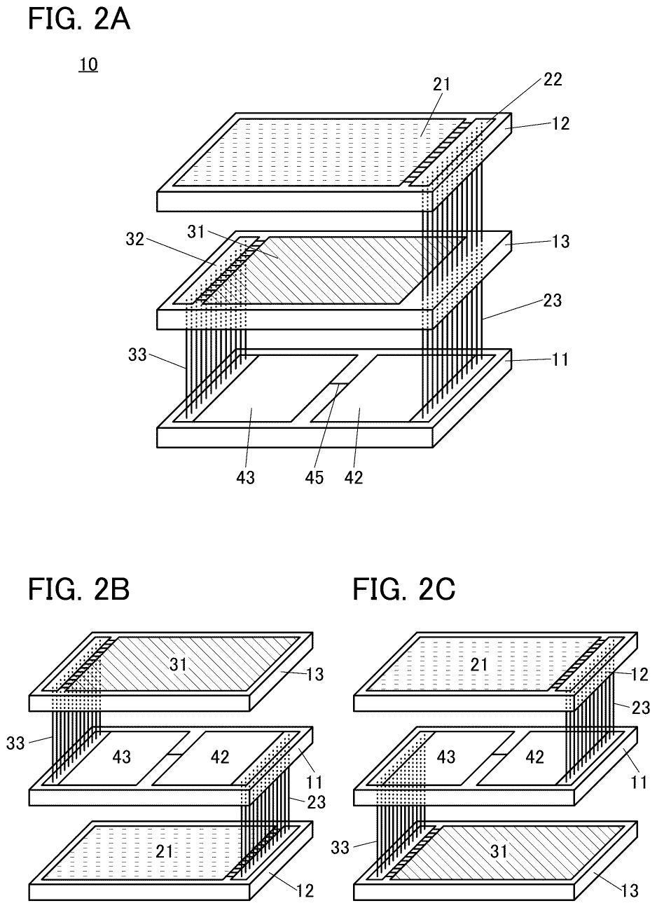

FIG. 2A is an example where the positions of the layer 12 and the layer 13 are interchanged. The layer 13 is positioned between the layer 11 and the layer 12. In that case, the plugs 23 partly penetrate the layer 13.

Alternatively, as illustrated in FIG. 2B, the layer 11 may be provided between the layer 12 and the layer 13. In FIG. 2B, the layer 11 is positioned over the layer 12, and the layer 13 is positioned over the layer 11.

In addition, FIG. 2C is an example where the positions of the layer 12 and the layer 13 in FIG. 2B are interchanged. The layer 11 is positioned over the layer 13, and the layer 12 is positioned over the layer 11.

As the structure illustrated in FIG. 2B or FIG. 2C, it is possible to employ a structure where neither the plug 23 nor the plug 33 penetrates other layers. Accordingly, the physical length of both of the plug 23 and the plug 33 can be shortened, so that operating speed can be increased. Furthermore, a region in the layer 12 that overlaps the plug 33 and a region in the layer 13 that overlaps the plug 23 can be used as the storage device 21 and the storage device 31, respectively, so that the data capacity of both of the storage device 21 and the storage device 31 can be increased.

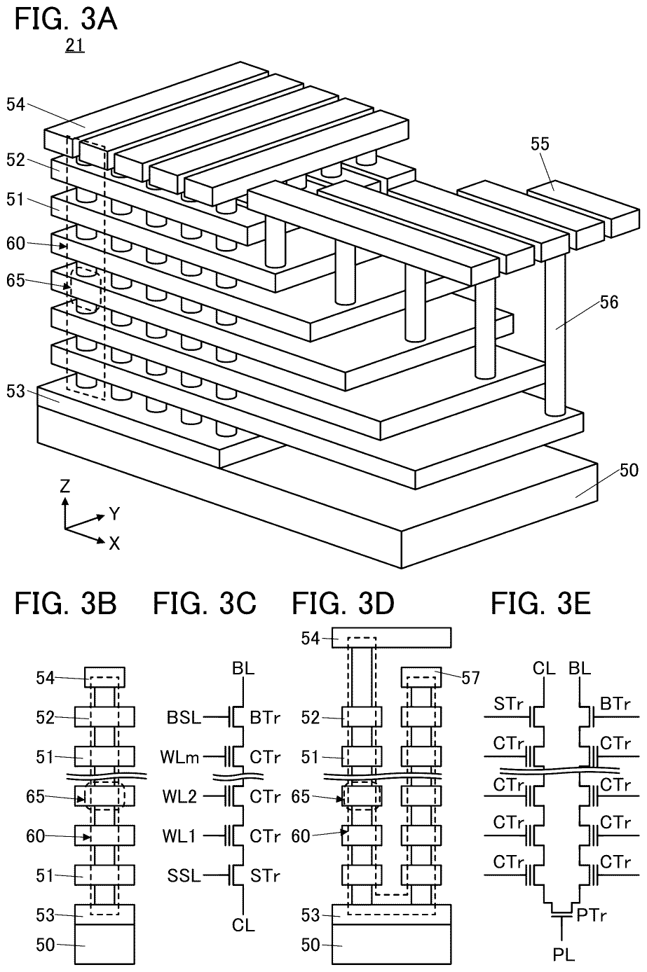

Next, an example of a structure that can be employed for the storage device 21 provided in the layer 12 is described. FIG. 3A is a schematic perspective view of the storage device 21.

The storage device 21 is provided over an insulating layer 50 and includes a plurality of memory strings 60. The memory strings 60 include a plurality of cell transistors stacked in a direction perpendicular to a top surface of the insulating layer 50. The storage device 21 further includes a plurality of conductive layers 51, a plurality of conductive layers 52, a conductive layer 53, a plurality of conductive layers 54, and a plurality of conductive layers 55 that function as a variety of wirings, and a plurality of plugs 56.

In FIG. 3A, an X direction, a Y direction, and a Z direction that are orthogonal to each other are each indicated by an arrow. The memory strings 60 are evenly spaced in each of the X direction and the Y direction. FIG. 3A illustrates one block including 5×5 memory strings 60 as an example. The storage device 21 includes a plurality of such blocks. Note that in fact, the number of memory strings 60 included in one block is preferably larger than 5×5.

One memory string 60 is provided to connect the conductive layer 53 and the conductive layer 54. For example, the conductive layer 53 functions as a source line, and the conductive layer 54 functions as a bit line. In addition, the plurality of conductive layers 51 are stacked and provided between the conductive layer 53 and the conductive layer 54. The conductive layer 51 functions as a control gate line. In addition, the conductive layer 52 functioning as a selection line is provided between the uppermost conductive layer 51 and the conductive layer 54. Furthermore, the plurality of conductive layers 51 are each connected to one of the plurality of conductive layers 55 through the plug 56.

The conductive layer 54 and the conductive layer 52 each extend in a direction where they intersect with each other and form a matrix of 5×5. In addition, the conductive layer 51 and the conductive layer 53 are connected to all the memory strings 60 in the block (here, 5×5 memory strings 60).

Note that although FIG. 3(A) illustrates the example of the structure including five conductive layers 51, the number of layers is not limited thereto. As the number of stacks becomes larger, the number of cell transistors included in one memory string 60 becomes larger; thus, the data capacity of the storage device 21 can be increased. It is preferable that the number of cell transistors included in one memory string 60 be as large as possible, and for example, the number of cell transistors included in one memory string 60 can be larger than or equal to 64, larger than or equal to 128, larger than or equal to 160, larger than or equal to 192, larger than or equal to 224, or larger than or equal to 256.

FIG. 3B illustrates an excerpt structure of one memory string 60 and its vicinity. A memory cell 65 functioning as a cell transistor is provided as a portion of the memory string 60 that intersects with the conductive layer 51. Among the plurality of conductive layers 51, the lowermost conductive layer 51 may also function as a selection line.

FIG. 3C is a circuit diagram of the structure illustrated in FIG. 3B. The conductive layer 53, the conductive layer 54, the lowermost conductive layer 51, the other conductive layers 51, and the conductive layer 52 correspond to a wiring CL, a wiring BL, a wiring SSL, wirings WL (a wiring WL1 to a wiring WLm (m is an integer greater than or equal to 2)), and a wiring BSL, respectively.

As illustrated in FIG. 3C, a transistor STr, a plurality of transistors CTr, and a transistor BTr are provided between the wiring BL and the wiring CL. The transistor STr and the transistor BTr each function as a selection transistor, and the transistor CTr functions as a cell transistor. The transistor CTr functions as one storage element.

For the transistor CTr, a charge trapping-type flash memory or a floating gate-type flash memory can be used, for example. Alternatively, it is possible to use a storage element utilizing a ferroelectric that has a structure where a ferroelectric capacitor is connected to a gate, a structure where a ferroelectric is employed for a gate insulating layer, or a structure where a ferroelectric capacitor is connected to one of a source and a drain, for example.

FIG. 3D and FIG. 3E correspond to an example where one memory string 60 is formed using a pair of memory strings in FIG. 3B and FIG. 3C. In that case, the conductive layer 53 functions as a pipe gate line, and a conductive layer 57 functions as a source line. A transistor PTr that is provided in a lower portion of a U-shaped memory string functions as a selection transistor (also referred to as a pipe transistor) for connecting the pair of memory strings. A wiring PL is connected to a gate of the transistor PTr.

Next, examples of structures that can be used for the storage device 21, the storage device 31, the driver circuit 42, and the driver circuit 43 are described.

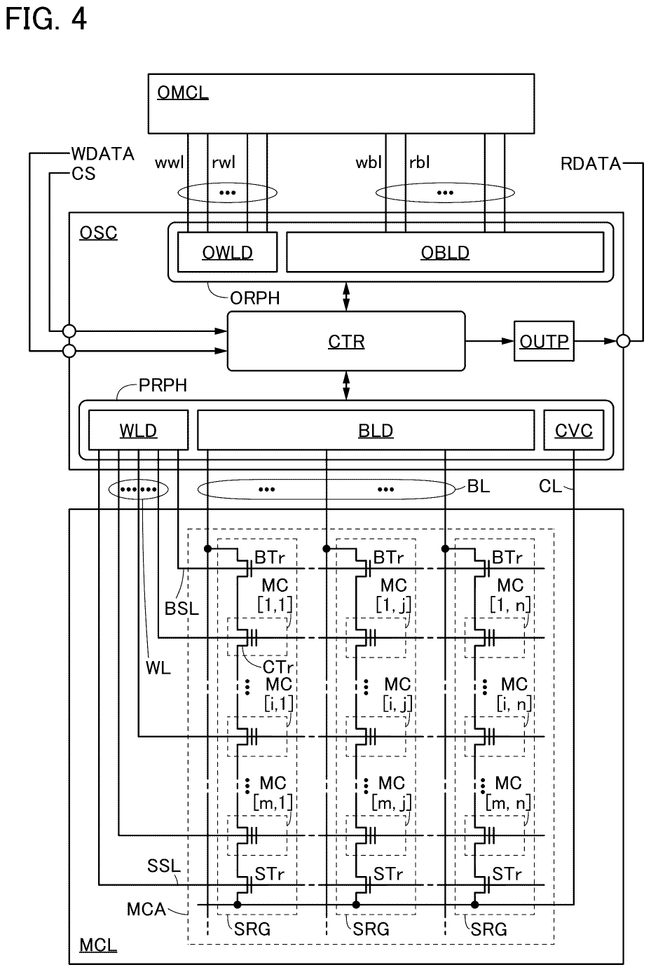

FIG. 4 is a block diagram illustrating a structure example of a circuit OSC and a memory cell portion MCL. The circuit OSC is a circuit that is included in the driver circuit 42 and the driver circuit 43, and the memory cell portion MCL is a circuit including memory cells of the storage device 21. FIG. 4 also illustrates a memory cell portion OMCL. The memory cell portion OMCL is a circuit including memory cells of the storage device 31.

The memory cell portion MCL includes a memory cell array MCA. The memory cell array MCA includes a plurality of strings SRG. The string SRG is electrically connected to the wiring BL. The string SRG includes the plurality of transistors CTr electrically connected in series and the transistor BTr and the transistor STr for selection. Note that one transistor CTr functions as a cell transistor and is included in a memory cell MC of the string SRG.

A cell transistor is a transistor that operates with normally-on characteristics and includes a control gate and a charge accumulation layer. The charge accumulation layer is provided in a region overlapping a channel formation region with a tunnel insulating film therebetween. The control gate is provided in a region overlapping the charge accumulation layer with a blocking film therebetween. In the cell transistor, tunnel current is generated when a write potential is applied to the control gate and a predetermined potential is applied to one of a first terminal and a second terminal of the cell transistor; hence, electrons are injected from the channel formation region into the charge accumulation layer of the cell transistor. Thus, the threshold voltage of the cell transistor in which electrons are injected into the charge accumulation layer is increased. Note that a floating gate may be used instead of the charge accumulation layer.

In addition, a structure where a ferroelectric capacitor is connected to a gate or a structure where a ferroelectric is used for a gate insulating layer can be used for the cell transistor. With such a structure, reliability can be further increased and power consumption can be reduced.

Channel formation regions of the transistor BTr, the transistor CTr, and the transistor STr preferably contain any one or more materials selected from silicon, germanium, gallium arsenide, silicon carbide (SiC), and a metal oxide, for example.

In the channel formation region, it is particularly preferable to use an oxide of one or more metals selected from indium, an element M (the element M is one or more elements selected from aluminum, gallium, yttrium, and tin, for example), and zinc. The metal oxide can be used as a wide gap semiconductor, and the transistor BTr, the transistor CTr, and the transistor STr each containing the metal oxide in the channel formation region can have a characteristic of extremely low off-state current. That is, leakage current of the transistor BTr, the transistor CTr, and the transistor STr in an off state can be reduced, so that power consumption of the storage device can be reduced in some cases.

Note that although FIG. 4 illustrates an example where the transistor BTr and the transistor STr are formed in the memory cell portion MCL, the transistor BTr and the transistor STr may be formed in the circuit OSC.

The memory cell array MCA includes a plurality of memory cells MC in the string SRG. The plurality of memory cells MC are arranged in a matrix. Note that the memory cell array MCA includes a total of m x n memory cells MC of m memory cells in one column and n memory cells in one row (m and n are each an integer greater than or equal to 2). The memory cell MC positioned in an i-th row and a j-th column (i is an integer greater than or equal to 1 and less than or equal to m, and j is an integer greater than or equal to 1 and less than or equal to n) is represented as MC[i,j].

The wirings WL are a plurality of word lines, and the wirings WL are each electrically connected to memory cells MC row by row. The wirings BL are a plurality of bit lines, and the wirings BL are each electrically connected to memory cells MC column by column. The wiring CL is a power supply line.

Next, a connection structure of the string SRG is described. The transistor BTr, the plurality of transistors CTr, and the transistor STr are connected in series, and the transistor BTr and the transistor STr are electrically connected to the wiring BL and the wiring BL, respectively.

The wiring BSL and the wiring SSL function as wirings for selecting a string when operation such as writing, reading, or erasing is performed. The wiring BSL is electrically connected to gates of the transistors BTr, and the wiring SSL is electrically connected to gates of the transistors STr.

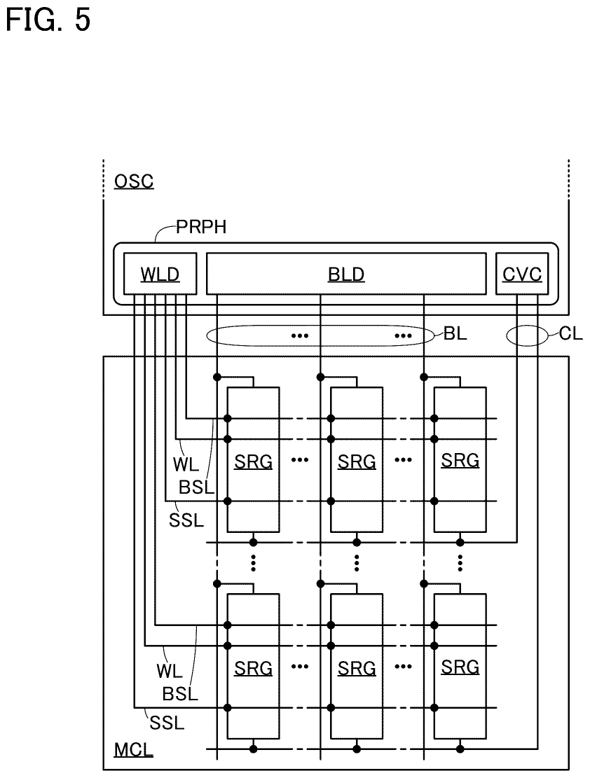

Note that although one string SRG is electrically connected to one wiring BL, one embodiment of the present invention is not limited thereto. For example, the memory cell portion MCL may have a structure where a plurality of strings SRG are electrically connected to one wiring BL, as illustrated in FIG. 5. Note that the block diagram of FIG. 5 illustrates the memory cell portion MCL and part of the circuit OSC.

The circuit OSC includes a control circuit CTR, a circuit PRPH, a circuit ORPH, and an output circuit OUTP. From the outside of the semiconductor device 10, a control signal CS (a clock signal, a chip enable signal, a write enable signal, an address signal, or the like) and a data signal WDATA are input to the control circuit CTR, for example.

The circuit PRPH corresponds to the driver circuit 42, and the circuit ORPH corresponds to the driver circuit 43. Here, although an example where the control circuit CTR and the output circuit OUTP are used in common between the circuit PRPH and the circuit ORPH is illustrated, one or both of the control circuit CTR and the output circuit OUTP may be independently provided.

The control circuit CTR has a function of accessing the circuit PRPH to write data to the memory cell portion MCL and a function of reading data from the memory cell portion MCL. In addition, the control circuit CTR has a function of accessing the circuit ORPH to write data to the memory cell portion OMCL and a function of reading data from the memory cell portion OMCL.

In the case where a write command by the control signal CS and the data signal WDATA are input to the control circuit CTR from the outside of the semiconductor device 10, the data signal WDATA is first written to the memory cell portion OMCL. Then, the written data is read from the memory cell portion OMCL, and the read data is written to the memory cell portion MCL. That is, it can also be said that the memory cell portion OMCL has a function of a cache memory of the memory cell portion MCL. Note that in the case where the data amount of the data signal WDATA is small, for example, the control circuit CTR may have a function of writing data directly to the memory cell portion MCL not through the memory cell portion OMCL.

In the case where a read command by the control signal CS is input to the control circuit CTR from the outside of the semiconductor device 10, the control circuit CTR reads data from the memory cell portion MCL (the control circuit CTR may read data from the memory cell portion OMCL in the case where the data exists in the memory cell portion OMCL), and outputs the data to the output circuit OUTP. The output circuit OUTP outputs a data signal RDATA to the outside of the semiconductor device 10. Note that the write command and the read command each include an address signal.

The control circuit CTR may have a function of detecting and correcting an error (also referred to as ECC: Error Check and Correct) in reading data from the memory cell portion MCL. The memory cell portion OMCL can function as a cache memory when the control circuit CTR detects and corrects an error. Note that the signals processed by the control circuit CTR and the functions of the control circuit CTR are not limited thereto; a different signal may be input (or output) as necessary, and the control circuit CTR may have a different function.

That is, the control circuit CTR can write the data signal WDATA input from the outside of the semiconductor device 10 to the memory cell portion OMCL, can read the written data from the memory cell portion OMCL, and can rewrite the read data to the memory cell portion MCL. The data signal WDATA input from the outside of the semiconductor device 10 is transferred through the plug in the semiconductor device 10; thus, the data transfer distance is short.

The semiconductor device 10 includes the memory cell portion OMCL. The data transfer distance between the memory cell portion OMCL and the memory cell portion MCL is short, which allows the semiconductor device 10 to have features of having less signal transmission delay, being capable of high-speed operation, and being capable of suppressing an increase in power consumption due to parasitic capacitance or the like, for example. The memory cell portion OMCL may have a function of a cache memory in the semiconductor device 10. In other words, the memory cell portion OMCL can be used as a storage device for temporarily storing data to be transmitted from the semiconductor device 10 to, for example, a processor, or data received from the processor.

The circuit PRPH includes a circuit WLD, a circuit BLD, and a circuit CVC, for example. The circuit WLD functions as a word line driver circuit and is electrically connected to the wirings WL. The circuit BLD functions as a bit line driver circuit and is electrically connected to the wirings BL. The circuit CVC functions as a power source that generates a constant potential and outputs the constant potential, and is electrically connected to the wiring CL. Note that the circuit CVC is not necessarily included in the circuit PRPH and may be provided outside the semiconductor device 10, for example. In that case, the constant potential is applied to the memory cell portion MCL of the semiconductor device 10 from the outside.

The circuit ORPH includes a circuit OWLD and a circuit OBLD, for example. The circuit OWLD functions as a word line driver circuit and is electrically connected to a wiring wwl and a wiring rwl. The circuit OBLD functions as a bit line driver circuit and is electrically connected to a wiring wbl and a wiring rbl.

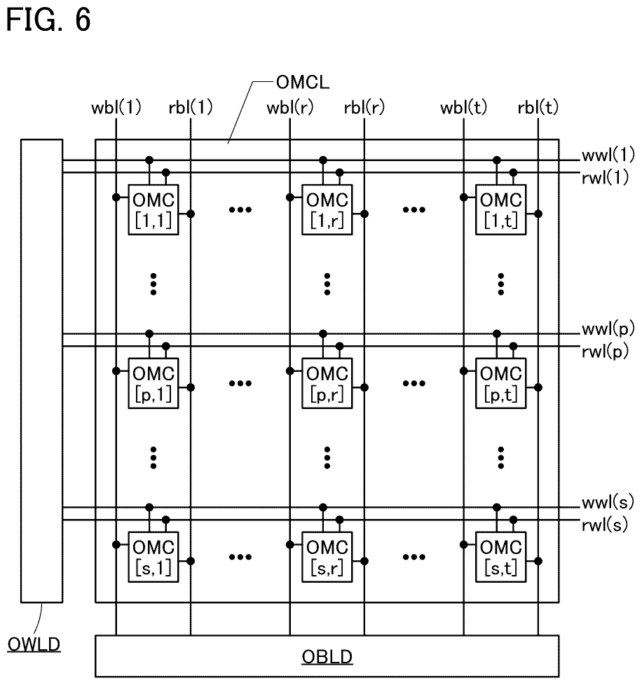

Next, a structure example of the memory cell portion OMCL is described. FIG. 6 is a block diagram illustrating a structure example of the memory cell portion OMCL.

The memory cell portion OMCL includes a total of s×t memory cells OMC of s memory cells in one column and t memory cells in one row (s and t are each an integer of greater than or equal to 2). The memory cells OMC are arranged in a matrix. The memory cell OMC positioned in a p-th row and an r-th column (p is an integer greater than or equal to 1 and less than or equal to s, and r is an integer greater than or equal to 1 and less than or equal to t) is represented as OMC[p,r] in FIG. 4. Note that the memory cell portion OMCL may have a structure where memory cells are three-dimensionally arranged as in the memory cell portion MCL.

Each of the wiring wwl and the wiring rwl is electrically connected to a plurality of memory cells OMC arranged in a row direction. In addition, each of the wiring wbl and the wiring rbl is electrically connected to a plurality of memory cells OMC arranged in a column direction.

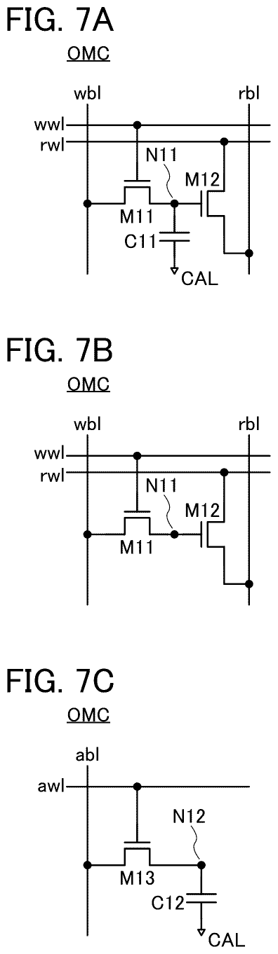

FIG. 7A is a circuit diagram illustrating a structure example of the memory cell OMC. The memory cell OMC includes a transistor M11, a transistor M12, and a capacitor C11.

One of a source and a drain of the transistor M11 is electrically connected to a gate of the transistor M12 and one terminal of the capacitor C11, the other of the source and the drain of the transistor M11 is electrically connected to the wiring wbl, and a gate of the transistor M11 is electrically connected to the wiring wwl. One of a source and a drain of the transistor M12 is electrically connected to the wiring rbl, and the other of the source and the drain of the transistor M12 is electrically connected to the wiring rwl. The other terminal of the capacitor C11 is electrically connected to a wiring CAL. A predetermined potential is applied to the wiring CAL. A connection portion to which the transistor M12 is connected is referred to as a node N11.

Note that in this specification and the like, expressions such as “terminal” are used in order to describe input and output of signals, potentials, and the like between components; however, in some cases, a physical connecting portion such as “terminal” does not exist in an actual circuit and the components are just electrically connected through a wiring, an electrode, or the like.

In the memory cell OMC, the wiring wbl functions as a write bit line, the wiring rbl functions as a read bit line, the wiring wwl functions as a write word line, and the wiring rwl functions as a read word line. The transistor M11 has a function of a switch for controlling conduction or non-conduction between the node N11 and the wiring wbl.

Data writing is performed in such a manner that a high-level potential is applied to the wiring wwl to bring the transistor M11 into a conduction state, and the node N11 and the wiring wbl are electrically connected. Specifically, when the transistor M11 is in a conduction state, a potential corresponding to data to be written is applied to the wiring wbl, and the potential is written to the node N11. Then, a low-level potential is applied to the wiring wwl to bring the transistor M11 into a non-conduction state so that the potential of the node N11 is retained.

Data reading is performed in such a manner that a predetermined potential is applied to the wiring rbl, and after that, the wiring rbl is brought into an electrically floating state and a low-level potential is applied to the wiring rwl. Hereinafter, applying a predetermined potential to the wiring and then bringing the wiring into a floating state are expressed as precharging the wiring.

For example, by precharging the bit line rbl with a potential Vdd, the transistor M12 has a potential difference between the source and the drain. Current flowing between the source and the drain of the transistor M12 is determined depending on a potential retained in the node N11; thus, the potential retained in the node N11 can be read by reading a change in the potential of the bit line rbl at the time when the bit line rbl is in a floating state.

A row where the memory cells OMC to which data is to be written are placed is selected by applying a high-level potential to the wiring wwl, and a row where the memory cells OMC from which data is to be read are placed is selected by applying a low-level potential to the wiring rwl. In contrast, a row where the memory cells OMC to which data is not written are placed can be in a non-selected state by applying a low-level potential to the wiring wwl, and a row where the memory cells OMC from which data is not read are placed can be in a non-selected state by applying, to the wiring rwl, the same potential as a potential with which the wiring rbl is precharged.

An OS transistor can be used as each of the transistor M11 and the transistor M12. Since the OS transistor has extremely low off-state current, a potential written to the node N11 can be retained for a long time when the OS transistor is used as the transistor M11. In other words, data written to the memory cell OMC can be retained for a long time. Alternatively, when the OS transistor is used as the transistor M11, the capacitance of the capacitor C11 may be made small in the memory cell OMC. Alternatively, when the OS transistor is used as the transistor M11, the memory cell OMC may have a structure without the capacitor C11, as illustrated in FIG. 7B. In the case where the memory cell OMC does not include the capacitor C11, a potential written to the node N11 is retained by the gate capacitance of the transistor M12, or the like.

The transistor M11 and the transistor M12 may each include a back gate (also referred to as a second gate or a bottom gate). For example, the threshold voltage of the transistor M11 can be increased or decreased by applying a predetermined potential to the back gate of the transistor M11. Alternatively, when the back gate of the transistor M11 is electrically connected to the gate (also referred to as a first gate, a top gate, or a front gate with respect to the back gate) of the transistor M11, the on-state current of the transistor M11 can be increased.

Specifically, by shifting the threshold voltage negatively, the on-state current of the transistor can be increased, and the memory cell OMC can operate at high speed. In contrast, by shifting the threshold voltage of the transistor M11 positively, the off-state current of the transistor can be reduced, and the memory cell OMC can retain data for a long time. Alternatively, different potentials may be applied to the back gates of the transistor M11 and the transistor M12. For example, the potential applied to the back gate of the transistor M11 may be low, and the potential applied to the back gate of the transistor M12 may be high.

Alternatively, a transistor other than the OS transistor may be used as each of the transistor M11 and the transistor M12. The transistor M11 is preferably a transistor with low off-state current, and for example, a transistor that includes a semiconductor with a wide band gap in a channel formation region can be used. The semiconductor with a wide band gap refers to a semiconductor whose band gap is larger than or equal to 2.2 eV in some cases, and examples of a material other than an oxide semiconductor include silicon carbide, gallium nitride, and diamond. In contrast, the transistor M12 is preferably a transistor with high on-state current, and a semiconductor material such as silicon or germanium may be used.

The memory cell OMC is a gain-cell-type memory cell including two transistors and one capacitor, or including two transistors and no capacitors. A gain-cell-type memory cell can operate as a memory by amplifying accumulated charge by the closest transistor even when the capacitance of accumulated charge is small. A gain-cell-type memory cell can read retained data without destruction (non-destructive reading).

Alternatively, the memory cell OMC may include one transistor and one capacitor. The memory cell OMC illustrated in FIG. 7C includes a transistor M13 and a capacitor C12.

One of a source and a drain of the transistor M13 is electrically connected to one terminal of the capacitor C12, the other of the source and the drain of the transistor M13 is electrically connected to a wiring abl, and a gate of the transistor M13 is electrically connected to a wiring awl. The other terminal of the capacitor C12 is electrically connected to the wiring CAL. A connection portion to which the one of the source and the drain of the transistor M13 is connected is referred to as a node N12.

An OS transistor can be used as the transistor M13 like the transistor M11 and the transistor M12. In the memory cell OMC illustrated in FIG. 7C, the wiring abl functions as a bit line and the wiring awl functions as a word line.

When the memory cell OMC has the structure illustrated in FIG. 7C, the arrangement density of the memory cells OMC can be improved, while data reading is destructive reading. The memory cell portion OMCL can perform random access to the memory cell OMC even when the memory cell OMC included in the memory cell portion OMCL is any of the memory cells OMC illustrated in FIG. 7A, FIG. 7B, and FIG. 7C.

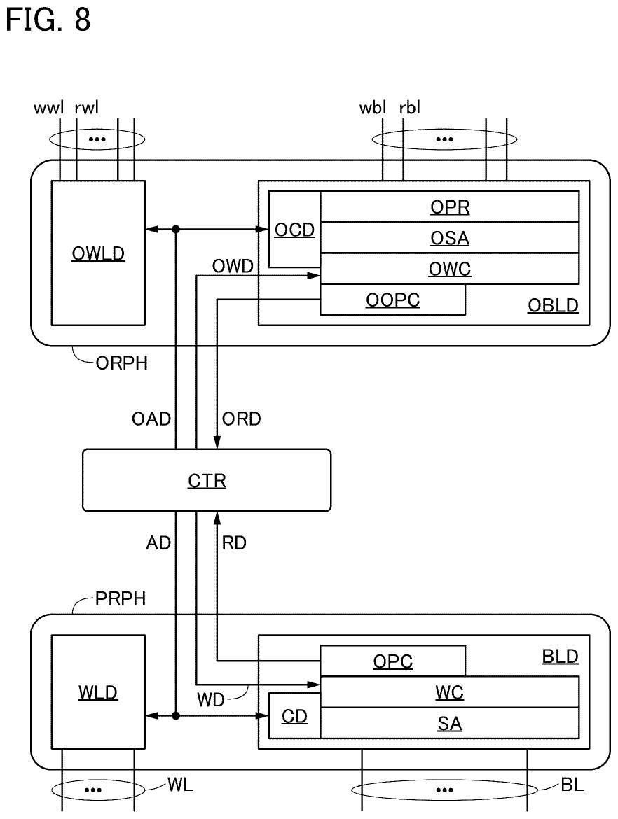

Next, the circuit BLD and the circuit OBLD included in the circuit OSC are specifically described. FIG. 8 is a block diagram illustrating a structure example of part of the circuit OSC. In FIG. 8, the output circuit OUTP, the circuit CVC, and the like are omitted from the circuit OSC illustrated in FIG. 4, and the structure example of the circuit BLD, the structure example of the circuit OBLD, and flow of signals in the circuit OSC are more specifically shown.

The circuit BLD can include a column decoder CD, a write circuit WC, a sense amplifier SA, and an output circuit OPC, for example.

The column decoder CD has a function of selecting the wiring BL electrically connected to the memory cell MC on which writing or reading is to be performed in accordance with an address signal AD obtained from the control circuit CTR. Here, the address signal AD is an internal signal of the circuit OSC and a signal corresponding to an address signal included in the control signal CS. The address signal AD is also transmitted to the circuit WLD. The circuit WLD has a function of driving the wiring BSL, the wiring WL, and the wiring SSL and a function of selecting the wiring WL electrically connected to the memory cell MC on which writing or reading is to be performed in accordance with the address signal AD.

The write circuit WC has a function of supplying, to the wiring BL selected by the column decoder CD, a potential corresponding to a data signal WD supplied from the control circuit CTR. Here, the data signal WD is an internal signal of the circuit OSC and a signal corresponding to a data signal ORD or the data signal WDATA.

The sense amplifier SA has a function of amplifying a data signal read from the wiring BL. Note that the amplified data signal is output to the control circuit CTR through the output circuit OPC as a data signal RD. The control circuit CTR outputs a signal corresponding to the data signal RD to the output circuit OUTP.

The circuit OBLD can include a column decoder OCD, a write circuit OWC, a precharge circuit OPR, a sense amplifier OSA, and an output circuit OOPC, for example.

The column decoder OCD has a function of selecting the wiring wbl and the wiring rbl electrically connected to the memory cell OMC on which writing or reading is to be performed in accordance with an address signal OAD obtained from the control circuit CTR. Here, the address signal OAD is an internal signal of the circuit OSC. The address signal OAD is also transmitted to the circuit OWLD. The circuit OWLD has a function of driving the wiring wwl and the wiring rwl and a function of selecting the wiring wwl and the wiring rwl electrically connected to the memory cell OMC on which writing or reading is to be performed in accordance with the address signal OAD.

The write circuit OWC has a function of supplying, to the wiring wbl selected by the column decoder OCD, a potential corresponding to a data signal OWD supplied from the control circuit CTR. Here, the data signal OWD is an internal signal of the circuit OSC and a signal corresponding to the data signal WDATA.

The precharge circuit OPR has a function of precharging the wiring rbl, and the sense amplifier OSA has a function of amplifying a data signal read from the wiring rbl. Note that the amplified data signal is output to the control circuit CTR through the output circuit OOPC as the data signal ORD. The control circuit CTR outputs a signal corresponding to the data signal ORD to the write circuit WC or the output circuit OUTP.

Note that the components of the circuit BLD and the circuit OBLD are not limited thereto; another component may be added as needed, or an unnecessary component may be reduced. The functions of the circuit BLD and the circuit OBLD are not limited thereto; another function may be added, or an unnecessary function may be reduced.

The above is the description of the semiconductor device 10 according to one embodiment of the present invention. According to one embodiment of the present invention, a highly versatile semiconductor device can be provided because the semiconductor device includes different kinds of memory devices in the same chip. In addition, data transfer speed between two memory devices can be improved. Furthermore, a semiconductor device that has a small occupied area can be achieved because the semiconductor device includes two kinds of memory devices in the same chip and peripheral circuits.

At least part of the structure examples, the drawings corresponding thereto, and the like described in this embodiment can be combined with the other structure examples, the other drawings, and the like as appropriate.

### Embodiment 2

In this embodiment, a structure example of a memory string according to one embodiment of the present invention and a semiconductor device using the memory string will be described.

### Memory String

A memory string 100 according to one embodiment of the present invention can be used for a 3D-NAND-type storage device. Note that in drawings illustrated below, an X direction, a Y direction, and a Z direction that are orthogonal to each other are each sometimes indicated by an arrow.

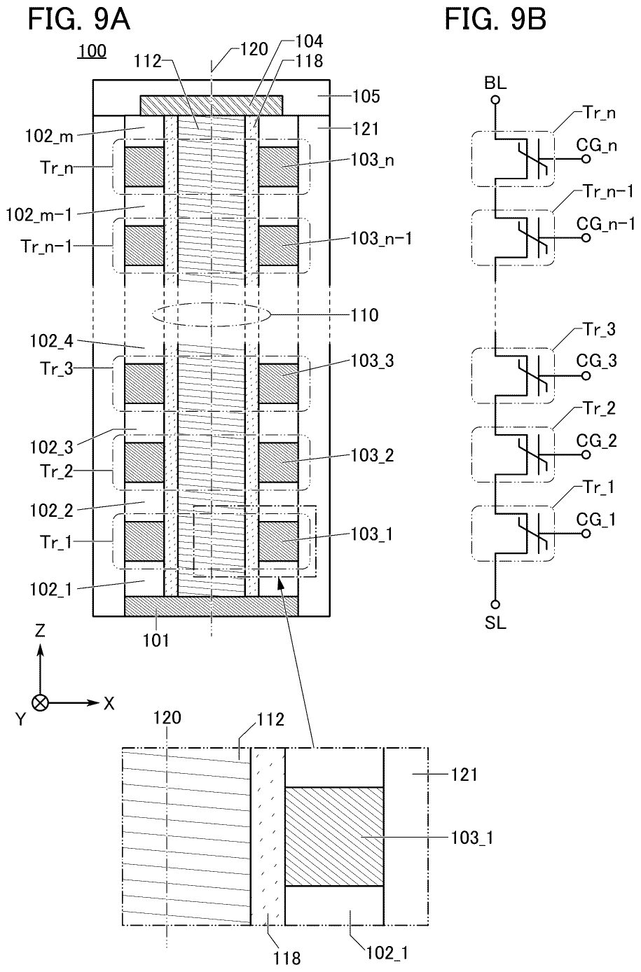

FIG. 9A is a cross-sectional view of the memory string 100 seen from the Y direction. Note that FIG. 9A illustrates a central axis 120 of the memory string 100 extending in the Z direction. In addition, FIG. 9B is an equivalent circuit of the memory string 100. The memory string 100 has a structure where a plurality of transistors Tr are connected in series. Wirings CG are connected to respective transistors.

Transistors Tr included in the memory string 100 each function as a ferroelectric transistor (FeFET: Ferroelectric FET). The ferroelectric transistor is a transistor using a ferroelectric for an insulator functioning as a gate insulator. The threshold voltage of the ferroelectric transistor can be changed when a certain voltage or higher is applied to the gate thereof. By using such transistors Tr, a NAND-type ferroelectric memory can be achieved.

The memory string 100 includes a conductive layer 101 placed above a substrate (not illustrated), m insulating layers 102 (m is an integer greater than or equal to 2), and n conductive layers 103 (nis an integer greater than or equal to 2). The insulating layers 102 and the conductive layers 103 are alternately stacked above the substrate. In FIG. 9A and the like, a first insulating layer 102 is referred to as an insulating layer 102_1, and an m-th insulating layer 102 is referred to as an insulating layer 102_m. Similarly, a first conductive layer 103 is referred to as a conductive layer 103_1, and an n-th conductive layer 103 is referred to as a conductive layer 103_n. Note that in this embodiment and the like, the simple term “insulating layer 102″ refers to any insulating layer 102. Similarly, the simple term ”conductive layer 103″ refers to any conductive layer 103.

In addition, the memory string 100 includes a conductive layer 104, an insulating layer 105, a structural body 110, and an insulating layer 121. The structural body 110 extends along the Z direction. Furthermore, the structural body 110 is provided between the conductive layer 101 and the conductive layer 104 to penetrate the insulating layer 102_1 to the insulating layer 102_m and the conductive layer 103_1 to the conductive layer 103_n.

The structural body 110 has a columnar structure including a semiconductor layer 112 and a functional layer 118. Specifically, the semiconductor layer 112 extends along the central axis 120, and the functional layer 118 is provided to surround its periphery. The semiconductor layer 112 has a cylindrical shape along the central axis 120, and the functional layer 118 is concentrically provided outside the semiconductor layer 112.

Note that the cross-sectional shape of the structural body 110 is not limited to a circle and may be a triangle, a rectangle, or a polygon with five or more corners. In addition, the outline of the structural body 110 in a cross section perpendicular to the Z direction may be formed of only a curve or may be a combination of a straight line and a curve.

The insulating layer 121 is provided to cover side surfaces of the insulating layer 102_1 to the insulating layer 102_m and the conductive layer 103_1 to the conductive layer 103_n. The conductive layer 104 is provided over the insulating layer 102_m. The conductive layer 101 and the conductive layer 104 are electrically connected to the semiconductor layer 112. In addition, the insulating layer 105 is provided over the insulating layer 102_m, the insulating layer 121, and the conductive layer 104.

An intersection portion of the structural body 110 and the conductive layer 103 functions as the transistor Tr. The transistor Tr functions as a memory cell (also referred to as a storage element).

The conductive layer 103 functions as a gate of the transistor Tr. The memory string 100 includes n intersection portions of the structural body 110 and the conductive layer 103. Thus, the memory string 100 includes n transistors Tr, that is, n memory cells.

In FIG. 9A and FIG. 9B, a first transistor Tr is referred to as a transistor Tr_1, and an n-th transistor Tr is referred to as a transistor Tr_n. Note that in this embodiment and the like, the simple term “transistor Tr” refers to any transistor Tr. The same applies to the wiring CG. A wiring CG that is connected to the n-th transistor Tr_n is referred to as a wiring CG_n.

As described above, polycrystalline silicon is used for a body portion of a 3D-NAND memory string in many cases. Note that in the memory string 100 according to one embodiment of the present invention, the semiconductor layer 112 corresponds to a body portion. For the semiconductor layer 112, a single crystal semiconductor, a polycrystalline semiconductor, a microcrystalline semiconductor, an amorphous semiconductor, or the like can be used alone or in combination. As a semiconductor material, silicon or germanium can be used, for example. Alternatively, a compound semiconductor such as silicon germanium, silicon carbide (SiC), gallium arsenide, an oxide semiconductor, or a nitride semiconductor may be used.

Alternatively, the semiconductor layer 112 may be a semiconductor having crystallinity increased by a catalytic element. As the catalytic element, an element selected from metal elements such as nickel (Ni), iron (Fe), cobalt (Co), ruthenium (Ru), rhodium (Rh), palladium (Pd), osmium (Os), iridium (Ir), platinum (Pt), copper (Cu), gold (Au), and germanium (Ge) is used.

For example, the crystallinity may be increased by forming amorphous silicon for the semiconductor layer 112, adding nickel as a catalytic element, and performing heat treatment. The catalytic element is bound to silicon to form a silicide. The catalytic element is likely to be bound to a portion with a number of defects, such as a portion in an amorphous state. Thus, the catalytic element contained in the silicide reacts with silicon in an amorphous state to form a new silicide. In this manner, crystallization proceeds while the silicide moves. When the catalytic element reaches a semiconductor including an impurity element such as a Group 15 element or a Group 13 element, the catalytic element can be inhibited from diffusing again.

In the case where nickel is added as a catalytic element in the semiconductor layer 112, the concentration of nickel elements might have a gradient in the semiconductor layer 112. For example, a region functioning as a channel of the transistor has a lower nickel concentration than another region (e.g., a source region or a drain region) in some cases. In other words, the source region and the drain region have a higher nickel concentration than the region functioning as the channel in some cases.

The semiconductor layer 112 functions as a semiconductor layer where a channel of the transistor Tr is formed. The semiconductor layer used in the transistor may be a stack of semiconductors. In the case where semiconductor layers are stacked, semiconductor materials having different crystal states may be used or different semiconductor materials may be used.

In particular, the transistor Tr is preferably a transistor using an oxide semiconductor, which is a kind of metal oxide, in the semiconductor layer 112 where a channel is formed. An oxide semiconductor has a bandgap higher than or equal to 2 eV, achieving extremely low off-state current. Thus, the power consumption of the memory string 100 can be reduced. Accordingly, the power consumption of a semiconductor device including the memory string 100 can be reduced.

A memory cell including an OS transistor can be referred to as an OS memory. Furthermore, the memory string 100 including the memory cell can also be referred to as an OS memory.

The on resistance of the OS transistor can be made smaller than that of a transistor using polycrystalline silicon for its semiconductor layer where a channel is formed. In other words, the conductivity of a body portion can be increased. When the OS transistor is used as the transistor Tr, the operating speed of the memory string 100 can be increased. In addition, the transistor using polycrystalline silicon has a variation in threshold voltage caused by a crystal grain boundary, whereas the OS transistor has little influence by a crystal grain boundary and a small variation in threshold voltage. Accordingly, when the OS transistor is used as the transistor Tr, malfunction caused by a variation in threshold voltage can be suppressed in the memory string 100.

In addition, the OS transistor operates stably even in a high-temperature environment and has small fluctuation in characteristics. For example, the off-state current hardly increases even in a high-temperature environment. Specifically, the off-state current hardly increases even at an environment temperature higher than or equal to room temperature and lower than or equal to 200° C. In addition, the on-state current is less likely to decrease even in a high-temperature environment. Thus, the memory string 100 including the OS memory achieves stable operation and high reliability even in the high-temperature environment. Furthermore, the OS transistor has a high withstand voltage between its source and drain. When the OS transistor is used as a transistor included in the memory string 100, it is possible to achieve the memory string 100 that stably operates and has high reliability even in the high-temperature environment. Accordingly, the reliability of the semiconductor device including the memory string 100 can be increased.

A NAND-type storage device including the OS memory is also referred to as an OS NAND-type or an OS NAND-type storage device. In addition, a 3D-NAND-type storage device including the OS memory is also referred to as a 3D OS NAND-type or a 3D OS NAND-type storage device. Thus, the memory string 100 according to one embodiment of the present invention can be referred to as a 3D OS NAND-type storage device.

A dielectric can be used for the functional layer 118.

When an electric field is applied to a dielectric, a positively charged portion and a negatively charged portion are generated inside the dielectric. Such a phenomenon is called polarization. A dielectric in which polarization disappears when an electric field vanishes is called paraelectric, and a dielectric in which polarization remains even when an electric field vanishes is called ferroelectric. The property in which polarization remains even when an electric field vanishes is called ferroelectricity.

A material exhibiting ferroelectricity is used for the functional layer 118. Examples of the material exhibiting ferroelectricity include oxides such as hafnium oxide, zirconium oxide, and hafnium zirconium oxide. A material obtained by adding a Group 3 (Group IIIa) element to these oxides is preferably used. For example, the oxide preferably contains one or more of scandium, yttrium, and an element belonging to lanthanoid. In particular, yttrium, lanthanum, or scandium is preferable because it is comparatively easy to handle and has high compatibility with a semiconductor manufacturing process. When such an element is added, not only stable ferroelectricity can be exhibited but also degradation of characteristics caused by repeated rewriting can be inhibited, so that reliability can be improved. Other examples of an additive element include silicon, aluminum, gadolinium, and scandium.

An oxide containing one or both of hafnium and zirconium easily exhibits ferroelectricity even when it is used in an extremely thin film formed by a deposition method of a thin film, such as a sputtering method or an ALD method, and thus the oxide has high compatibility with a semiconductor manufacturing process and can reduce manufacturing cost.

Alternatively, for the functional layer 118, a piezoelectric ceramic having a perovskite structure, such as barium titanate, lead titanate, strontium titanate, barium strontium titanate (BST), lead zirconate titanate (PZT), strontium bismuth tantalate (SBT), or bismuth ferrite (BFO) may be used.

Alternatively, for the functional layer 118, an organic ferroelectric such as polyvinylidene fluoride (PVDF) or a copolymer of vinylidene fluoride (VDF) and trifloroethylene (TrFE) may be used.

As the material exhibiting ferroelectricity, a mixture or a compound containing a plurality of materials selected from the above-listed materials can be used, for example. Alternatively, the functional layer 118 can have a stacked structure of a plurality of materials selected from the above-listed materials.

Hafnium oxide or a material containing hafnium oxide and zirconium oxide (HZO) is preferable as the material exhibiting ferroelectricity because it exhibits ferroelectricity even when processed into a several-nanometer-thick thin film. With the use of hafnium oxide or hafnium zirconium oxide, the film thickness of the functional layer 118 can be less than or equal to 100 nm, preferably less than or equal to 50 nm, further preferably less than or equal to 20 nm, still further preferably less than or equal to 10 nm.

In the case where hafnium zirconium oxide (HfZrOx (X is a real number greater than 0)) is used as the material exhibiting ferroelectricity, deposition is preferably performed by an atomic layer deposition (ALD) method, particularly a thermal ALD method. It is preferable to use an ALD method (including a thermal ALD method) using plasma to increase reactivity (a PEALD method (Plasma Enhanced ALD)).

In the case of using a thermal ALD method, it is suitable to use a material that does not contain hydrocarbon (also referred to as Hydro Carbon or HC) for a precursor. Either or both of hydrogen and carbon contained in a film might hinder crystallization. Therefore, the concentration of either or both of hydrogen and carbon contained in the film is preferably reduced by using a precursor that does not contain hydrocarbon. Examples of the precursor that does not contain hydrocarbon include a chlorine-based material. Note that in the case of using hafnium zirconium oxide, a chlorine-based precursor such as HfCl₄ or ZrCl₄ is used as a precursor.

In the case where a film of hafnium zirconium oxide is used for the functional layer 118, it is preferable that hafnium oxide and zirconium oxide be alternately deposited at a ratio of 1:1 by a thermal ALD method or an ALD method using plasma.

As an oxidizer used for a thermal ALD method or an ALD method using plasma, H₂O or O₃ can be used. Note that the oxidizer is not limited thereto and may contain any one or more selected from O₂, O₃, N₂O, NO₂, H₂O, and H₂O₂.

An impurity concentration in a film used for the functional layer 118 is preferably low. In particular, the concentrations of hydrogen (H) and carbon (C) are preferably as low as possible. Specifically, the hydrogen concentration in the film is preferably lower than or equal to 5×10²⁰atoms/cm³ , further preferably lower than or equal to 1×10²⁰atoms/cm³ . The carbon concentration in the film is preferably lower than or equal to 5×10¹⁹atoms/cm³, further preferably lower than or equal to 1×10¹⁹atoms/cm³.

A crystal structure of the film used for the functional layer 118 is not particularly limited as long as the crystal structure is non-centrosymmetric and has polarity. For example, a crystal system except a cubic crystal system can be employed. The film used for the functional layer 118 may have a single crystal structure or a polycrystalline structure, or may have a composite structure including an amorphous structure and a crystal structure.

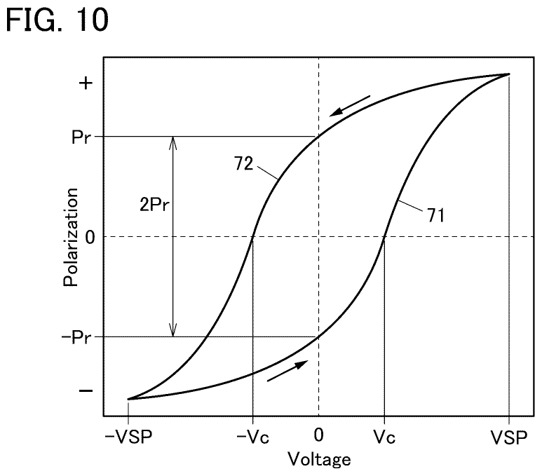

A layer that exhibits ferroelectricity and is used for the functional layer 118 is also referred to as a ferroelectric layer. The ferroelectric layer has hysteresis characteristics. FIG. 10 is a graph showing an example of hysteresis characteristics. In FIG. 10, a horizontal axis represents voltage (electric field) applied to the ferroelectric layer, and a vertical axis represents polarization of the ferroelectric layer. The electric field strength can be obtained by dividing the voltage by the thickness of the ferroelectric layer.

The hysteresis characteristics of the ferroelectric layer can be represented by a curve 71 and a curve 72. Voltages at intersection points of the curve 71 and the curve 72 are referred to as a saturation polarization voltage VSP and a saturation polarization voltage-VSP.

After a voltage lower than or equal to −VSP is applied to the ferroelectric layer, the voltage applied to the ferroelectric layer is increased, so that polarization of the ferroelectric layer is increased according to the curve 71. In contrast, after a voltage higher than or equal to VSP is applied to the ferroelectric layer, the voltage applied to the ferroelectric layer is decreased, so that polarization of the ferroelectric layer is decreased according to the curve 72. Note that in some cases, VSP is referred to as a positive saturation polarization voltage or a first saturation polarization voltage, and −VSP is referred to as a negative saturation polarization voltage or a second saturation polarization voltage. The absolute value of the first saturation polarization voltage may be the same as or different from the absolute value of the second saturation polarization voltage.

Here, a voltage when the polarization of the ferroelectric layer changes according to the curve 71 to reach 0 is referred to as a coercive voltage Vc. In addition, a voltage when the polarization of the ferroelectric layer changes according to the curve 72 to reach 0 is referred to as a coercive voltage −Vc. The value of Vc and the value of −Vc are each a value between −VSP and VSP. Note that in some cases, Vc is referred to as a positive coercive voltage or a first coercive voltage, and −Vc is referred to as a negative coercive voltage or a second coercive voltage. The absolute value of the first coercive voltage may be the same as or different from the absolute value of the second coercive voltage.

The polarization of the ferroelectric layer is easily inverted when a voltage higher than the coercive voltage is applied to the ferroelectric layer. In the case where the polarization of the ferroelectric layer functioning as a gate insulating layer in an FeFET is not to be inverted, a voltage applied between a gate and a source (also referred to as a gate voltage or Vg) is set higher than or equal to −Vc and lower than or equal to Vc. In order to control an on state and an off state of the FeFET without inversion of the polarization of the ferroelectric layer functioning as a gate insulating layer, the absolute value of the coercive voltage is preferably large.

The maximum value and the minimum value of polarization when a voltage is not applied to the ferroelectric layer (when the voltage is 0 V) are referred to as remanent polarization Pr and remanent polarization-Pr, respectively. The absolute value of the difference between the remanent polarization Pr and the remanent polarization-Pr is referred to as remanent polarization 2Pr. A larger remanent polarization 2Pr increases the range of a change in threshold voltage due to polarization inversion. Thus, the remanent polarization 2Pr is preferably as large as possible.

Note that as the functional layer 118, a charge accumulation layer may be used instead of the ferroelectric layer. For example, by using a stacked structure of a blocking layer, a charge accumulation layer, and a tunnel layer for the functional layer 118, it is possible to achieve a transistor functioning as a memory cell that stores data by retaining charge in the charge accumulation layer.

Such a memory cell is sometimes referred to as various names depending on a stack structure from a control gate to a semiconductor. For example, in the case where a control gate, a blocking layer, a charge accumulation layer, a tunnel layer, and a semiconductor layer are formed using a metal, an oxide, a nitride, an oxide, and a semiconductor, respectively, such a memory cell is referred to as a MONOS (Metal Oxide Nitride Oxide Semiconductor)-type memory cell.

Alternatively, the memory cell may be a SONOS (Silicon Oxide Nitride Oxide Semiconductor)-type memory cell using n-type silicon or p-type silicon for a control gate, a TANOS (Tantalum nitride Aluminium oxide Nitride Oxide Semiconductor)-type memory cell using tantalum nitride and aluminum oxide for a control gate and a blocking layer, respectively, or a THNOS (Tantalum nitride Hafnium oxide Nitride Oxide Semiconductor)-type memory cell using tantalum nitride and hafnium oxide for a control gate and a blocking layer, respectively.

For example, a stacked structure of a silicon oxide film, a silicon nitride film, and a silicon oxide film from the semiconductor layer 112 side can be used for the functional layer 118. In that case, the silicon nitride film functions as a charge accumulation layer.

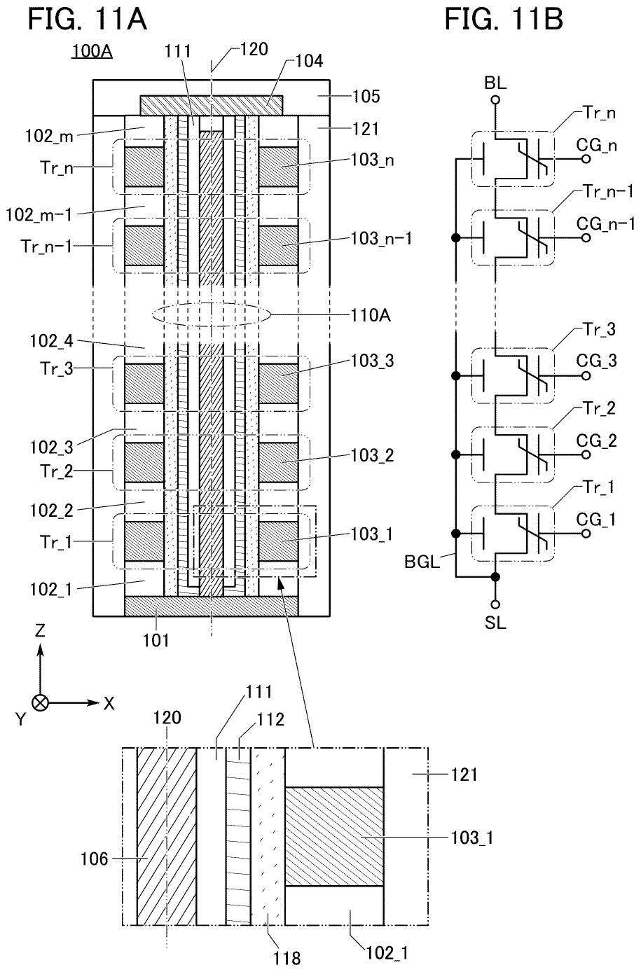

FIG. 11A and FIG. 11B illustrate a memory string 100A that includes back gates. The memory string 100A differs from the memory string 100 mainly in including a conductive layer 106 and an insulating layer 111. A structural body 110A of the memory string 100A includes the conductive layer 106, the insulating layer 111, the semiconductor layer 112, and the functional layer 118.

The memory string 100A includes the conductive layer 106 positioned at a central axis, and the insulating layer 111, the semiconductor layer 112, and the functional layer 118 are concentrically provided in this order to surround the conductive layer 106.

The conductive layer 106 functions as back gates of the transistors Tr. The insulating layer 111 functions as a back gate insulator of each of the transistors Tr.

In FIG. 11B, the back gates of the transistors Tr (the transistor Tr_1 to the transistor Tr_n) are electrically connected to a wiring SL through a wiring BGL. Note that the conductive layer 106 can function as the wiring BGL. In other words, the potential of the wiring SL is applied to the back gate of each of the transistors Tr. This stabilizes the threshold voltage of each of the transistors Tr compared to when there are no back gates, and enables more reliable write and erase operation.

### Semiconductor Device

Next, more specific structure examples of the semiconductor device including two types of storage devices as illustrated in Embodiment 1 are described.

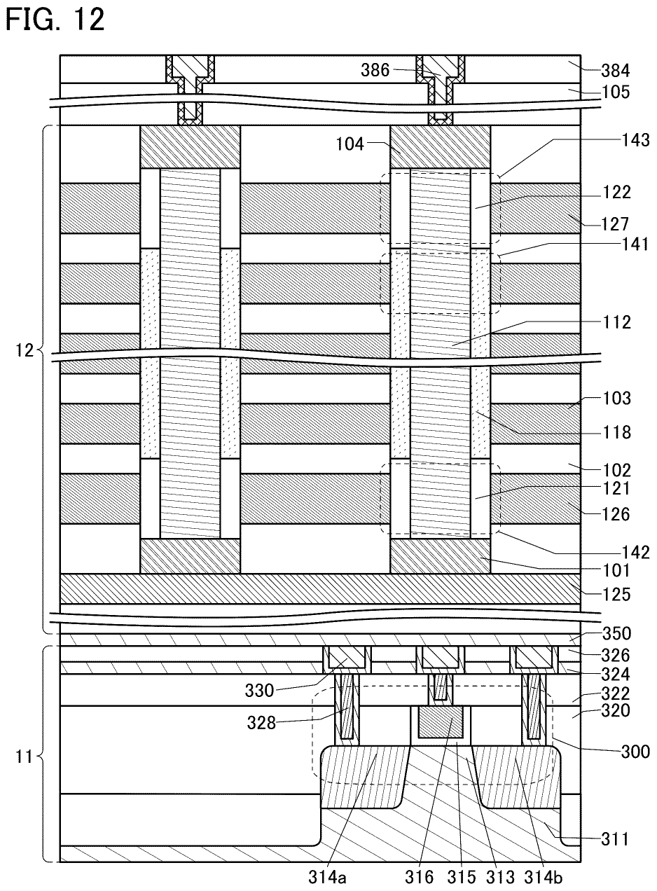

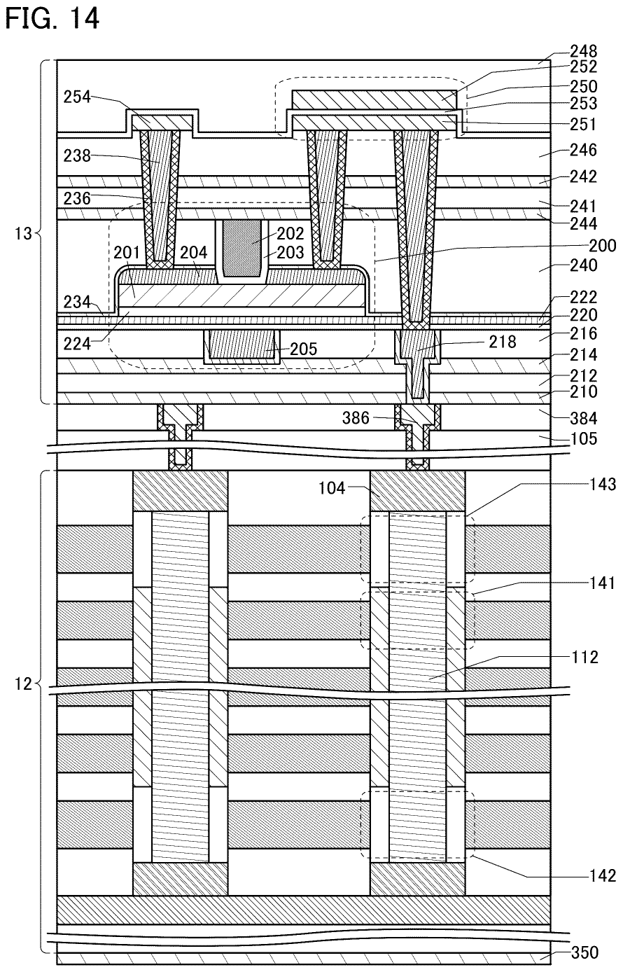

FIG. 12 illustrates a cross-sectional structure example of the layer 11 and the layer 12, and FIG. 14 illustrates a cross-sectional structure example of the layer 12 and the layer 13.

The case is described using FIG. 12 and FIG. 14 in which a circuit using a single crystal silicon substrate as a substrate is employed as the layer 11, a storage device including a NAND-type memory with a 3D structure is employed as the layer 12, and a storage device including an OS transistor is employed as the layer 13.

In FIG. 12, a transistor 300 is provided in the layer 11, and a plurality of memory strings are provided in the layer 12.

Each of the memory strings provided in the layer 12 includes a transistor 141, a plurality of transistors 142, and a transistor 143. Note that a detailed description of portions in the structure of the layer 12 that can be referred to for the memory string 100 illustrated in FIG. 9 is omitted and only different portions are described.

### Layer 11

The transistor 300 included in the layer 11 is provided on a substrate 311 and includes a conductive layer 316, an insulating layer 315, a semiconductor region 313 formed of part of the substrate 311, and a low-resistance region 314a and a low-resistance region 314b functioning as a source region and a drain region. FIG. 12 illustrates a cross section of the transistor 300 in a channel length direction.

It is preferable that the transistor 300 be what is called a Fin-type transistor in which a top surface of the semiconductor region 313 and side surfaces of the semiconductor region 313 in the channel width direction are covered with the conductive layer 316 with the insulating layer 315 therebetween in a cross section of the transistor 300 in a channel width direction. This improves the on-state characteristics of the transistor 300 because effective channel width increases. In addition, contribution of the electric field of a gate electrode can be increased, so that the off-state characteristics of the transistor 300 can be improved.

Note that the transistor 300 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably include a semiconductor such as a silicon-based semiconductor, and preferably include single crystal silicon. Alternatively, these regions may be formed using a material containing Ge (germanium), SiGe (silicon germanium), GaAs (gallium arsenide), GaN (gallium nitride), GaAlAs (gallium aluminum arsenide), or the like. A structure using silicon whose effective mass is controlled by applying stress to a crystal lattice and changing lattice spacing may be employed. Alternatively, the transistor 300 may be an HEMT (High Electron Mobility Transistor) by using GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to the semiconductor material employed for the semiconductor region 313.

For the conductive layer 316 functioning as a gate electrode, a semiconductor material such as silicon containing the element that imparts n-type conductivity, such as arsenic or phosphorus, or the element that imparts p-type conductivity, such as boron, or a conductive material such as a metal material, an alloy material, or a metal oxide material can be used.

Note that since a work function depends on the material of the conductor, the threshold voltage (Vth) of the transistor can be adjusted by changing the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

Note that the transistor 300 illustrated in FIG. 12 is an example and the structure is not limited thereto; an appropriate transistor is used in accordance with a circuit structure, a driving method, or the like.

An insulating layer 320, an insulating layer 322, an insulating layer 324, and an insulating layer 326 are sequentially stacked and provided to cover the transistor 300.

For the insulating layer 320, the insulating layer 322, the insulating layer 324, and the insulating layer 326, silicon oxide, silicon oxynitride, silicon nitride oxide, silicon nitride, aluminum oxide, aluminum oxynitride, aluminum nitride oxide, or aluminum nitride is used, for example.

The insulating layer 322 may have a function of a planarization film for eliminating a level difference caused by the transistor 300 or the like provided below the insulating layer 322. For example, a top surface of the insulating layer 322 may be planarized by planarization treatment using a chemical mechanical polishing (CMP) method or the like to increase planarity.

In addition, for the insulating layer 324, it is preferable to use a film having a barrier property that prevents diffusion of hydrogen, impurities, or the like from the substrate 311, the transistor 300, or the like into a region where the transistor 141 and the like are provided.

For the film having a barrier property against hydrogen, for example, silicon nitride formed by a CVD method can be used. Here, diffusion of hydrogen into a semiconductor element including an oxide semiconductor, such as the transistor 141, degrades the characteristics of the semiconductor element in some cases. Therefore, a film that inhibits hydrogen diffusion is preferably used between the transistor 141 and the like, and the transistor 300. The film that inhibits hydrogen diffusion is specifically a film from which a small amount of hydrogen is released.

The amount of released hydrogen can be analyzed by a thermal desorption spectroscopy (TDS) analysis method or the like, for example. The amount of hydrogen released from the insulating layer 324 that is converted into hydrogen atoms per area of the insulating layer 324 is less than or equal to 10×10¹⁵atoms/cm² , preferably less than or equal to 5×10¹⁵atoms/cm² , in TDS analysis in a film-surface temperature range of 50° C. to 500° C., for example.

Note that the permittivity of the insulating layer 326 is preferably lower than that of the insulating layer 324. For example, the relative permittivity of the insulating layer 326 is preferably lower than 4, further preferably lower than 3. In addition, the relative permittivity of the insulating layer 326 is, for example, preferably 0.7 times or less, further preferably 0.6 times or less the relative permittivity of the insulating layer 324. When a material with low relative permittivity is used for an interlayer film, parasitic capacitance generated between wirings can be reduced.

In addition, a conductive layer 328, a conductive layer 330, and the like are embedded in the insulating layer 320, the insulating layer 322, the insulating layer 324, and the insulating layer 326. Note that the conductive layer 328 and the conductive layer 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material for each of the plugs and wirings (the conductive layer 328, the conductive layer 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to form the plugs and wirings with a low-resistance conductive material such as aluminum or copper. The use of a low-resistance conductive material can reduce wiring resistance.

Although not illustrated in FIG. 12, a wiring layer may be provided over the insulating layer 326 and the conductive layer 330. For example, it is preferable that an insulator having a barrier property against hydrogen like the insulating layer 324 be provided over the insulating layer 326 and the conductive layer 330 and that a conductor having a barrier property against hydrogen be formed in the insulator. When the conductor having a barrier property against hydrogen is formed in an opening portion of the insulator having a barrier property against hydrogen, the transistor 300 can be separated from the transistor 141 and the like by a barrier layer, and hydrogen diffusion into the transistor 141 and the like from the transistor 300 can be inhibited.

For the conductor having a barrier property against hydrogen, tantalum nitride is preferably used, for example. In addition, by stacking tantalum nitride and tungsten, which has high conductivity, hydrogen diffusion from the transistor 300 can be inhibited while the conductivity as a wiring is kept. In that case, a structure is preferable in which a tantalum nitride layer having a barrier property against hydrogen is in contact with the insulator having a barrier property against hydrogen. Note that in FIG. 12, an insulating layer 350 having a barrier property against hydrogen is provided over the insulating layer 326 and the conductive layer 330.

### Layer 12

The layer 12 includes a conductive layer 125, a plurality of conductive layers 103, a conductive layer 126, a conductive layer 127, the insulating layer 121, an insulating layer 122, the functional layer 118, the semiconductor layer 112, the conductive layer 101, the conductive layer 104, and the like.

The insulating layer 121 functions as a gate insulating layer of the transistor 142, and the insulating layer 122 functions as a gate insulating layer of the transistor 143. The conductive layer 125 functions as a wiring. The conductive layer 126 functions as a gate of the transistor 142, and the conductive layer 127 functions as a gate of the transistor 143.

An insulating layer 384 is provided over the insulating layer 105. A conductive layer 386 reaching the conductive layer 104 is provided in the insulating layer 105 and the insulating layer 384. The conductive layer 386 functions as a plug.

For the conductive layer 125, it is possible to use a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like, for example. Alternatively, a semiconductor having high electrical conductivity, typified by polycrystalline silicon containing an impurity element such as phosphorus, or silicide such as nickel silicide may be used. A conductive material containing a metal element such as titanium or tantalum and nitrogen may be used. For example, a conductive material containing nitrogen, such as titanium nitride or tantalum nitride, may be used. Alternatively, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used, for example. Alternatively, indium gallium zinc oxide containing nitrogen may be used, for example. Using such a material sometimes allows capture of hydrogen or water mixed from a surrounding insulator or the like.

There is no particular limitation on a method for forming the conductive layer 125. The conductive layer 125 can be deposited by a sputtering method, a CVD method (including a thermal CVD method, an MOCVD method, a PECVD method, or the like), an MBE (Molecular Beam Epitaxy) method, an ALD (Atomic Layer Deposition) method, or a PLD (Pulsed Laser Deposition) method, for example.

A material with low permittivity is preferably used for the insulating layer 102. Accordingly, capacitance between the conductive layer 126 and the conductive layer 103, between the conductive layers 103, or between the conductive layer 103 and the conductive layer 127 can be reduced, and the driving speed of the semiconductor device can be improved.

A material containing silicon oxide or silicon oxynitride can be used for the insulating layer 102, for example. Alternatively, for example, it is possible to use a single layer or a stacked layer of an insulator including a material selected from boron, carbon, nitrogen, oxygen, fluorine, magnesium, aluminum, silicon, phosphorus, chlorine, argon, gallium, germanium, yttrium, zirconium, lanthanum, neodymium, hafnium, tantalum, and the like. The insulating layer 102 can be deposited by a deposition method such as a sputtering method, a CVD method (including a thermal CVD method, an MOCVD method, a PECVD method, or the like), an MBE method, an ALD method, or a PLD method, for example.

For the conductive layer 103, the conductive layer 126, and the conductive layer 127, a material similar to that of the conductive layer 125 can be used.

For the conductive layer 101 and the conductive layer 104, silicon in which an impurity is diffused is preferably used, for example. As the impurity, an n-type impurity (donor) can be used. As the n-type impurity, phosphorus or arsenic can be used, for example. Alternatively, as the impurity, a p-type impurity (accepter) can be used. As the p-type impurity, boron, aluminum, or gallium can be used, for example. As silicon, single crystal silicon, hydrogenated amorphous silicon, microcrystalline silicon, polycrystalline silicon, or the like can be used, for example. Alternatively, besides silicon, a metal oxide with high carrier density can be employed for the conductive layer 101 and the conductive layer 104 in some cases. Alternatively, Ge or a compound semiconductor such as ZnSe, CdS, GaAs, InP, GaN, or SiGe can be employed in some cases.

A material employed for each of the conductive layer 101 and the conductive layer 104 is preferably the same as a material for the semiconductor layer 112. In addition, in that case, the carrier density of each of the conductive layer 101 and the conductive layer 104 is preferably higher than that of the semiconductor layer 112.

For the semiconductor layer 112, silicon is preferably used. As silicon, single crystal silicon, hydrogenated amorphous silicon, microcrystalline silicon, polycrystalline silicon, or the like can be used, for example. For the semiconductor layer 112, a metal oxide other than silicon can be used in some cases. Alternatively, Ge or a compound semiconductor such as ZnSe, CdS, GaAs, InP, GaN, or SiGe can be employed in some cases.

Examples of the metal oxide that can be used for the semiconductor layer 112 include In oxide, Ga oxide, and Zn oxide. The metal oxide preferably contains at least In or Zn. The metal oxide preferably contains two or three selected from In, an element M, and Zn. Note that the element Mis a metal element or a metalloid element that has high binding energy with oxygen, such as a metal element or a metalloid element whose binding energy with oxygen is higher than that of indium, for example. Specific examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The element M included in the metal oxide is preferably one or more kinds of the above elements, and specifically, the element M is preferably one or more kinds selected from Al, Ga, Y, and Sn, and is further preferably Ga.

When a metal oxide is an In-M-Zn oxide, the atomic ratio of In is preferably higher than or equal to the atomic ratio of M in the In-M-Zn oxide. Examples of the atomic ratio of the metal elements in such an In—M—Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood thereof. Note that a composition in the neighborhood includes the range of ±30 % of an intended atomic ratio. By increasing the atomic ratio of indium in the metal oxide, the on-state current, field-effect mobility, or the like of the transistor can be increased.

The atomic ratio of In may be less than the atomic ratio of M in the In-M-Zn oxide. Examples of the atomic ratio of the metal elements in such an In—M—Zn oxide include In:M:Zn=1:3:2, In:M:Zn=1:3:3, In:M:Zn=1:3:4, and a composition in the neighborhood thereof. By increasing the atomic ratio of M in the metal oxide, generation of oxygen vacancies can be inhibited.

For the semiconductor layer 112, for example, an In oxide, an In—Zn oxide, an In—Ga oxide, an In—Sn oxide, an In—Ti oxide, an In—Ga—Al oxide, an In—Ga—Sn oxide, an In—Ga—Zn oxide, an In—Sn—Zn oxide, an In—Al—Zn oxide, an In—Ti—Zn oxide, an In—Ga—Sn—Zn oxide, or an In—Ga—Al—Zn oxide, or the like can be used. Alternatively, a Ga—Zn oxide may be used. A material that does not contain Zn, such as indium oxide, is preferable because compatibility with an LSI manufacturing process is increased. In contrast, a material that contains Zn is preferable because crystallinity can be easily increased.

In particular, it is preferable to use an In—Zn oxide where the atomic ratio of the metal elements is In:Zn=4:1, In:Zn=2:1, or its vicinity; an In—Sn—Zn oxide where the atomic ratio of the metal elements is In:Sn:Zn=4:0.1:1, In:Sn:Zn=2:0.1:1, or its vicinity; or the like because the field-effect mobility of the transistor can be appropriately increased.

Note that the metal oxide may contain, instead of indium or in addition to indium, one or more kinds of metal elements with larger period numbers. As overlap between orbits of metal elements is larger, carrier conductivity in the metal oxide tends to be higher. Thus, when the transistor includes metal elements with larger period numbers, the field-effect mobility of the transistor can be increased in some cases. Examples of the metal elements with larger period numbers include metal elements that belong to Period 5 and metal elements that belong to Period 6. Specific examples of the metal elements include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may contain one or more kinds of nonmetallic elements. When the metal oxide contains the nonmetallic elements, the field-effect mobility of the transistor can be increased in some cases. Examples of the nonmetallic element include carbon, nitrogen, phosphorus, sulfur, selenium, fluorine, chlorine, bromine, and hydrogen.

A sputtering method or an atomic layer deposition (ALD) method can be suitably used for forming the metal oxide. In particular, the metal oxide is preferably deposited by ALD, which provides excellent coverage. Note that in the case where the metal oxide is formed by a sputtering method, the composition of the deposited metal oxide is sometimes different from the composition of a target. In particular, the content of zinc in the deposited metal oxide is sometimes reduced to approximately 50 % of that of the target.

In this specification and the like, the content of a certain metal element in the metal oxide refers to the ratio of the number of atoms of the element to the total number of atoms of metal elements contained in the metal oxide. In the case where a metal oxide contains a metal element X, a metal element Y, and a metal element Z whose atomic numbers are respectively represented by Ax, Ay, and Az, the content of the metal element X can be represented by Ax/(Ax+Ay+Az). Moreover, in the case where the atomic ratio of the metal element X to the metal element Y and the metal element Z contained in the metal oxide is represented by Bx:By:Bz, the content of the metal element X can be represented by Bx/(Bx+By+Bz).

For example, in the case of the metal oxide containing In, a higher content of In enables the transistor to have high on-state current.

With the use of a metal oxide that does not contain Ga or has a low Ga content in the semiconductor layer 112, the transistor can be highly reliable against positive bias application. That is, the amount of change in the threshold voltage of the transistor in the PBTS (Positive Bias Temperature Stress) test can be small. Meanwhile, in the case of using a metal oxide that contains Ga, the Ga content is preferably lower than the In content. This achieves the transistor with high mobility and high reliability.

Meanwhile, the high content of Ga enables the transistor to be highly reliable against light. That is, the amount of change in the threshold voltage of the transistor in the NBTIS (Negative Bias Temperature Illumination Stress) test can be small. Specifically, in a metal oxide in which the atomic ratio of Ga is higher than or equal to that of In, the band gap is increased and accordingly the amount of change in the threshold voltage of the transistor in the NBTIS test can be reduced.

Furthermore, a metal oxide having a high Zn content has high crystallinity, so that diffusion of impurities in the metal oxide can be inhibited. Consequently, a change in the electrical characteristics of the transistor can be inhibited and the reliability can be increased.

The semiconductor layer 112 may have a stacked-layer structure of two or more metal oxide layers. The two or more metal oxide layers included in the semiconductor layer 112 may have the same composition or substantially the same compositions. With the stacked-layer structure of metal oxide layers having the same composition, for example, manufacturing cost can be reduced because the metal oxide layers can be formed using the same sputtering target. Note that a stacked-layer structure including two or more oxide semiconductor layers having different compositions may be employed. The use of an ALD method can form a metal oxide layer with a composition that continuously changes in a thickness direction. This not only increases the range of choices for design compared with the case of using a film with a predetermined composition but also prevents generation of an interface state or the like between two layers with different compositions; thus, the electrical characteristics and reliability can be increased.

It is preferable to use a metal oxide layer having crystallinity as the semiconductor layer 112. For example, a metal oxide layer having a CAAC (c-axis aligned crystal) structure, a polycrystalline structure, a microcrystalline (nc: nano-crystal) structure, or the like can be used. With the use of the metal oxide layer having crystallinity as the semiconductor layer 112, the density of defect states in the semiconductor layer 112 can be reduced, which enables the semiconductor device to have high reliability.

The higher the crystallinity of the metal oxide layer used as the semiconductor layer 112 is, the lower the density of defect states in the semiconductor layer 112 can be. In contrast, the use of a metal oxide layer having low crystallinity enables a transistor through which a large amount of current can flow.

For the functional layer 118, the above description can be referred to. FIG. 12 is an example where a dielectric exhibiting ferroelectricity is used.

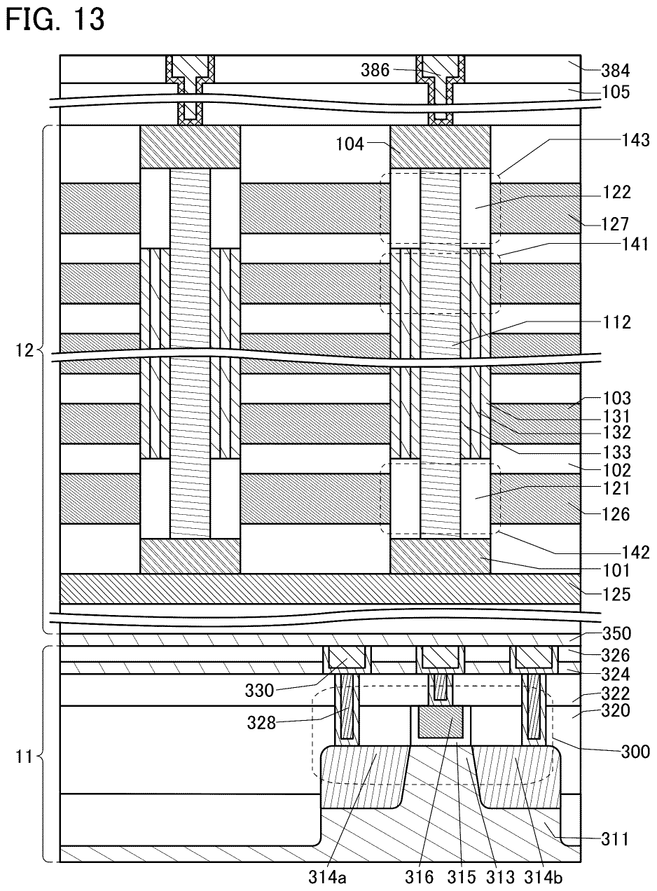

In addition, FIG. 13 is an example where a stacked structure of an insulating layer 131, an insulating layer 132, and an insulating layer 133 is used instead of the functional layer 118. For example, the insulating layer 132 functions as a charge accumulation layer. For example, a silicon oxide film, a silicon nitride film, and a silicon oxide film can be used for the insulating layer 131, the insulating layer 132, and the insulating layer 133, respectively. The transistor 141 illustrated in FIG. 13 functions as a charge trapping-type cell transistor. Note that without being limited thereto, a floating gate-type cell transistor can also be employed.

### Layer 13

As illustrated in FIG. 14, the layer 13 is provided over the layer 12. The layer 13 includes a transistor 200 and a capacitor 250.

The transistor 200 is a transistor including a metal oxide in a channel formation region (an OS transistor). The transistor 200 includes a pair of gates with a semiconductor where a channel is formed sandwiched therebetween. The transistor 200 has a characteristic of extremely low off-state current. For example, by using the transistor 200 as the transistor M11 of the memory cell OMC illustrated in the above embodiment, data written to the memory cell OMC can be retained for a long time. In addition, the transistor 200 can also be employed as the transistor M12. Furthermore, the capacitor 250 can be employed as the capacitor C11 or the capacitor C12 in the above embodiment.

In the layer 13, insulating films such as an insulating layer 210, an insulating layer 212, an insulating layer 214, an insulating layer 216, an insulating layer 220, an insulating layer 222, an insulating layer 240, an insulating layer 244, an insulating layer 241, an insulating layer 242, an insulating layer 246, and an insulating layer 248 are stacked over the insulating layer 384. The insulating layer 212, the insulating layer 216, the insulating layer 240, the insulating layer 241, the insulating layer 246, and the insulating layer 248 function as interlayer insulating films, and a material similar to that of the insulating layer 102 can be used. In addition, for each of the insulating layer 210, the insulating layer 214, the insulating layer 220, the insulating layer 222, the insulating layer 244, the insulating layer 242, and the like, it is preferable to use an insulating film that has a barrier property for preventing diffusion of hydrogen, an impurity, and the like.

A conductive layer 218 is provided to be embedded in the insulating layer 210, the insulating layer 212, the insulating layer 214, and the insulating layer 216. The conductive layer 218 functions as a plug. In FIG. 14, the conductive layer 218 is provided in contact with the conductive layer 386.

The transistor 200 includes a conductive layer 205 placed to be embedded in the insulating layer 214 and the insulating layer 216; the insulating layer 220 and the insulating layer 222 over the insulating layer 216 and the conductive layer 205; an insulating layer 224 over the insulating layer 222; a semiconductor layer 201 over the insulating layer 224; a pair of conductive layers 204 over the semiconductor layer 201; the insulating layer 240 that is positioned over the conductive layers 204 and includes a groove reaching the semiconductor layer 201; and an insulating layer 203 and a conductive layer 202 provided to be embedded in the insulating layer 240.

One of the pair of conductive layers 204 functions as a source electrode, and the other of the pair of conductive layers 204 functions as a drain electrode. The conductive layer 202 functions as a first gate electrode, and the insulating layer 203 functions as a first gate insulating layer. The conductive layer 205 functions as a second gate electrode, and the insulating layer 220, the insulating layer 222, and the insulating layer 224 function as a second gate insulating layer.

An oxide is preferably used for each of the insulating layer 224 and the insulating layer 203 that are in contact with the semiconductor layer 201. For example, an oxide such as silicon oxide, silicon oxynitride, aluminum oxide, or hafnium oxide is preferably used. Alternatively, a nitride such as silicon nitride, silicon nitride oxide, or aluminum nitride may be used. Alternatively, a single layer or a stacked layer of an insulator containing what is called a high-k material such as aluminum oxide, hafnium oxide, tantalum oxide, or zirconium oxide is preferably used. As miniaturization and high integration of a transistor progress, a problem such as leakage current might arise because of a thinner gate insulating film. Therefore, when a high-k material is used for an insulator functioning as a gate insulating film, a gate potential during transistor operation can be reduced while physical film thickness is maintained.

For the insulating layer 203, a stacked film where a plurality of insulating films are stacked is preferably used. For example, it is preferable to use a stacked film where two layers, three layers, or four or more layers of a film of the insulating material are stacked.

Alternatively, for the insulating layer 203, it is preferable to use a thin film including the material exhibiting ferroelectricity illustrated in Embodiment 1. Accordingly, the transistor 200 can be used as a nonvolatile storage element. In that case, a structure without using the capacitor 250 may be employed.

An insulating layer 234 is provided to cover the conductive layer 204 and has a function of inhibiting oxidation of the conductive layer 204. In that case, the insulating layer 234 is provided to cover side surfaces of the semiconductor layer 201 and side surfaces of the insulating layer 224 and to be in contact with the insulating layer 222. For the insulating layer 234, it is preferable to use an insulating film that has a barrier property for preventing diffusion of hydrogen, an impurity, and the like.

The capacitor 250 is provided over the insulating layer 246. The capacitor 250 includes a conductive layer 251, a conductive layer 252, and an insulating layer 253 positioned therebetween. The capacitor 250 is what is called a MIM (Metal-Insulator-Metal) capacitor.

It is preferable to use a single layer or a stacked layer of an insulator including the high-k material for the insulating layer 253. Alternatively, it is possible to use the material exhibiting ferroelectricity illustrated in Embodiment 1 for the insulating layer 253. Accordingly, the capacitor 250 can be a ferroelectric capacitor, and a combination of the capacitor 250 and the transistor 200 can achieve a nonvolatile memory cell.

In addition, a conductive layer 254 functioning as a wiring may be provided over the insulating layer 246. The conductive layer 254 can be formed by processing the same conductive film as that for the conductive layer 251.

The conductive layer 254 and the conductive layer 204 are connected with a conductive layer 236 and a conductive layer 238 therebetween. The conductive layer 236 and the conductive layer 238 function as a plug. For the conductive layer 236 and the conductive layer 238, materials similar to those of the conductive layer 328 and the conductive layer 330 can be used.

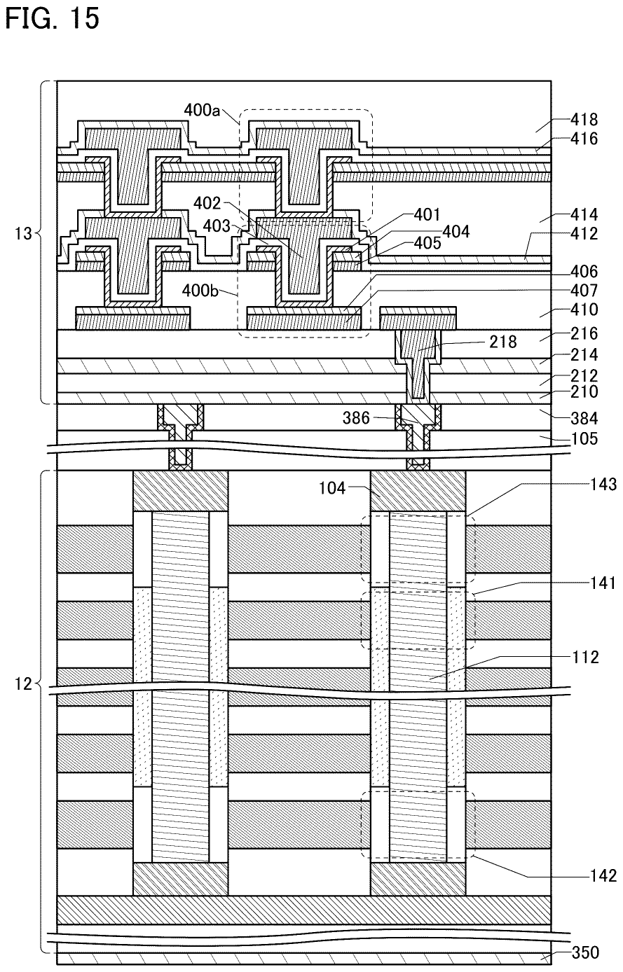

FIG. 15 illustrates an example of a different structure of the layer 13. In FIG. 15, a transistor 400a and a transistor 400b are provided in the layer 13. Each of the transistor 400a and the transistor 400b is a vertical transistor.

The transistor 400a and the transistor 400b each include a semiconductor layer 401, a conductive layer 402 functioning as a gate electrode, an insulating layer 403 functioning as a gate insulating layer, a conductive layer 404 functioning as one of a source electrode and a drain electrode, and a conductive layer 406 functioning as the other of the source electrode and the drain electrode.

A structure of the transistor 400b is described. A conductive layer 407 is provided over the insulating layer 216, the conductive layer 406 is provided over the conductive layer 407, and an insulating layer 410 is provided to cover the conductive layer 406. A conductive layer 405 is provided over the insulating layer 410, and the conductive layer 404 is provided over the conductive layer 405. An opening reaching the conductive layer 406 is provided in the conductive layer 404, the conductive layer 405, and the insulating layer 410. The semiconductor layer 401 is in contact with the conductive layer 404 and the conductive layer 406, and is in contact with side surfaces of the insulating layer 410 positioned in the opening. The insulating layer 403 is provided to cover the semiconductor layer 401, and the conductive layer 402 is provided to fill the opening.

In one or both of the transistor 400a and the transistor 400b, it is possible to use a thin film including the material exhibiting ferroelectricity illustrated in Embodiment 1 for the insulating layer 403 functioning as a gate insulating layer. In particular, it is preferable to employ such a thin film for the insulating layer 403 of the transistor 400b. Accordingly, the transistor 400b can be used as a nonvolatile storage element.

The channel length of the transistor 400b can be precisely controlled by the thickness of the insulating layer 410; thus, a variation in the channel length can be extremely smaller than that of a planar transistor. Furthermore, by reducing the thickness of the insulating layer 410, a transistor with extremely short channel length can be manufactured. For example, it is possible to manufacture a transistor with a channel length of smaller than or equal to 2 μm, smaller than or equal to 1 μm, smaller than or equal to 500 nm, smaller than or equal to 300 nm, smaller than or equal to 200 nm, smaller than or equal to 100 nm, smaller than or equal to 50 nm, smaller than or equal to 30 nm, or smaller than or equal to 20 nm and larger than or equal to 5 nm, larger than or equal to 7 nm, or larger than or equal to 10 nm. Therefore, a transistor with a channel length of less than 10 nm can also be achieved without using an extremely expensive light-exposure apparatus used in a cutting-edge LSI technology.

A variety of semiconductor materials can be used for the semiconductor layer 401; in particular, an oxide semiconductor containing a metal oxide is preferably used. The use of an oxide semiconductor formed under an appropriate condition allows a transistor having both high on-state current and extremely low off-state current to be achieved at low cost. Unless otherwise specified, suitable structure examples are described below given that an oxide semiconductor is used for the semiconductor layer 401.

The top surfaces of the conductive layer 404 and the conductive layer 406 are in contact with the semiconductor layer 401. Hence, in the case where an oxide semiconductor is used for the semiconductor layer 401, the vicinities of surfaces of the conductive layer 404 and the conductive layer 406 might be oxidized by the effect of heat or the like generated in a deposition step of a semiconductor film to be the semiconductor layer 401 or a later step, so that an insulating oxide film is formed between the conductive layers and the semiconductor layer 401, which increases contact resistance. Thus, an oxide conductor containing a conductive oxide is preferably used at least for the uppermost part of each of the conductive layer 404 and the conductive layer 406. This can prevent an increase in the contact resistance due to oxidation of the surfaces of the conductive layer 404 and the conductive layer 406. The conductive layer 404 and the conductive layer 406 can also be each referred to as an oxide layer, a metal oxide layer, an oxide conductor layer, or the like.

The conductive layer 405 can be used as one of a source wiring and a drain wiring. Part of the conductive layer 407 can be used as the other of the source wiring and the drain wiring. In the case where the conductive layer 405 and the conductive layer 407 are provided in contact with the conductive layer 404 and the conductive layer 406, respectively, in this manner, wiring electric resistance can be reduced. Thus, a material having higher conductivity than an oxide conductor, such as a metal, an alloy, or a nitride thereof, is preferably used for each of the conductive layer 405 and the conductive layer 407.

The semiconductor layer 401 is provided in contact with an inner wall in the opening in the insulating layer 410. An oxide insulating film is preferably used for the insulating layer 410. In particular, an oxide insulating film that releases oxygen by heating is preferably used. Furthermore, it is preferable that the insulating layer 410 have a structure where three or more layers are stacked and an oxide insulating film is sandwiched between insulating films each having a barrier property against oxygen (for example, nitride insulating films). This enables oxygen included in the oxide insulating film to be enclosed in a region surrounded by a pair of nitride insulating films and the semiconductor layer 401, and can prevent oxygen in the oxide insulating film from being released and decreased in the process, so that oxygen can be supplied to the semiconductor layer 401 more efficiently.

The transistor 400a has a structure similar to that of the transistor 400b except that an insulating layer 414 is used instead of the insulating layer 410 and that the conductive layer 402 is used instead of the conductive layer 406.

The gate electrode of the transistor 400b also serves as one of the source electrode and the drain electrode of the transistor 400a. For example, the transistor 400a corresponds to the transistor M11 in the structure illustrated in FIG. 7B, and the transistor 400b corresponds to the transistor M12.

The insulating layer 410, the insulating layer 414, and an insulating layer 418 function as interlayer insulating films. For each of an insulating layer 412, an insulating layer 416, and the like, it is preferable to use an insulating film that has a barrier property against hydrogen, an impurity, and the like.

In the transistor with the above structure, the source electrode and the drain electrode are positioned at different heights, so that current flows through the semiconductor in the height direction. In other words, the channel length direction can be regarded as having a component of a height direction (vertical direction); hence, the transistor according to one embodiment of the present invention can also be referred to as a VFET (Vertical Field Effect Transistor), a vertical transistor, a vertical-channel transistor, and the like. Since the source electrode, the semiconductor, and the drain electrode of the transistor can be provided to overlap each other, the area occupied by the transistor can be significantly reduced as compared with that occupied by what is called a planar transistor (also referred to as a lateral transistor, an LFET (Lateral FET), or the like) in which a semiconductor is placed over a flat plane.

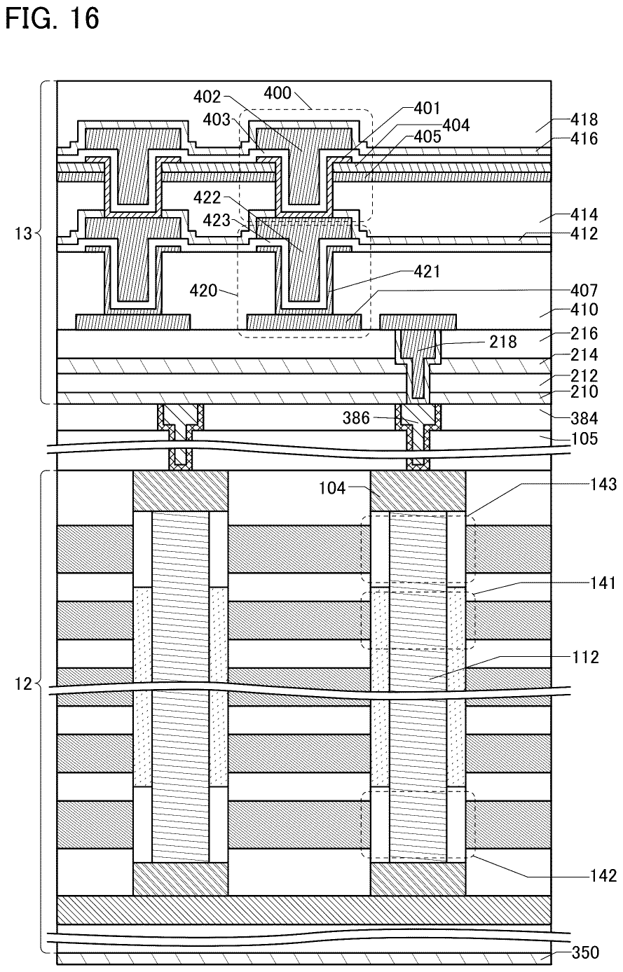

FIG. 16 illustrates a structure example that is partly different from that in FIG. 15. The layer 13 illustrated in FIG. 16 includes a transistor 400 having a structure similar to that of the transistor 400a and includes a capacitor 420 instead of the transistor 400b.

The capacitor 420 includes a conductive layer 421, a conductive layer 422, and an insulating layer 423 sandwiched therebetween. The insulating layer 423 functions as a dielectric layer of the capacitor 420. In addition, the conductive layer 407 is provided in contact with the conductive layer 421 and functions as a wiring.

In the insulating layer 410, an opening reaching the conductive layer 407 is provided. The conductive layer 421 is provided in contact with a top surface of the insulating layer 410, side surfaces of the insulating layer 410 positioned in the opening, and a top surface of the conductive layer 407 positioned in a bottom portion of the opening. The insulating layer 423 is provided to cover the conductive layer 421, and the conductive layer 422 is provided to cover the insulating layer 423.

It is preferable to use a single layer or a stacked layer of an insulator including the high-k material for the insulating layer 423. Alternatively, it is possible to use the material exhibiting ferroelectricity illustrated in Embodiment 1 for the insulating layer 423. Accordingly, the capacitor 420 can be a ferroelectric capacitor, and a combination of the capacitor 420 and the transistor 400 can achieve a nonvolatile memory cell.

For example, the transistor 400 corresponds to the transistor M13 in the structure illustrated in FIG. 7C, and the capacitor 420 corresponds to the capacitor C12.

By employing a structure where a vertical transistor and a vertical capacitor overlap each other in this manner, the area occupied by memory cells can be made extremely small. Therefore, a storage device that is easily highly integrated and has large capacity can be achieved.

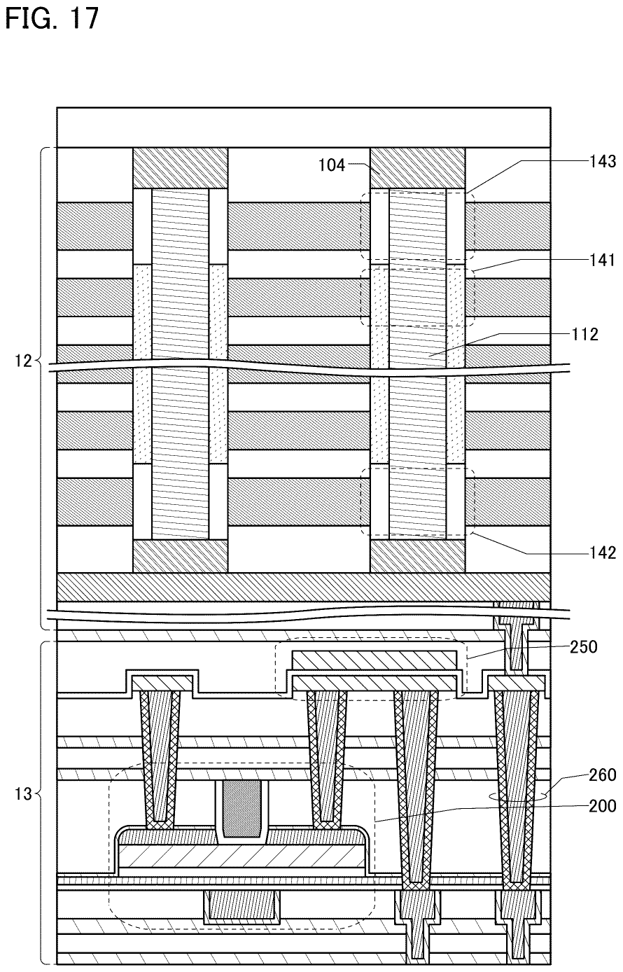

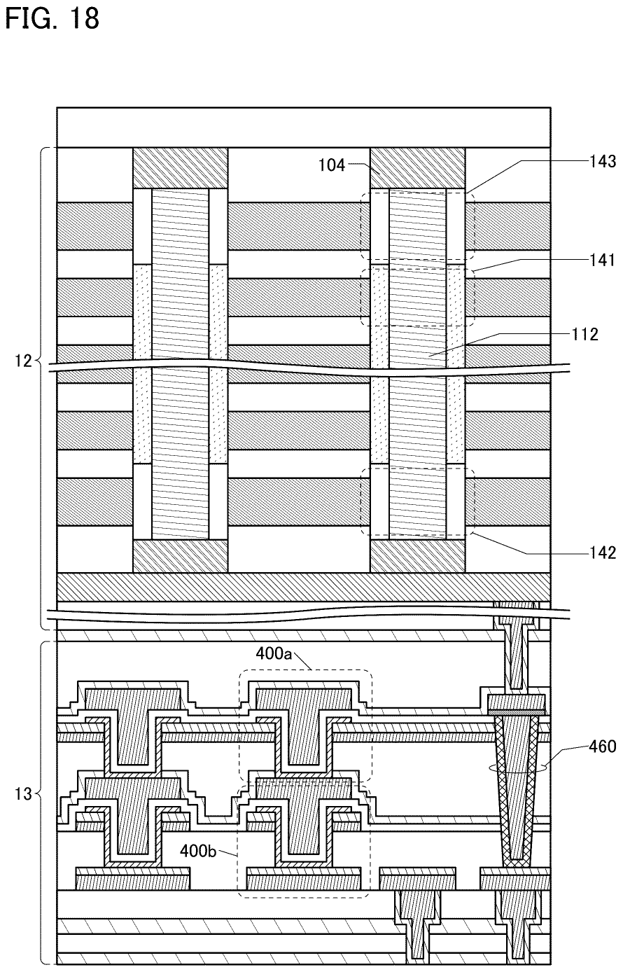

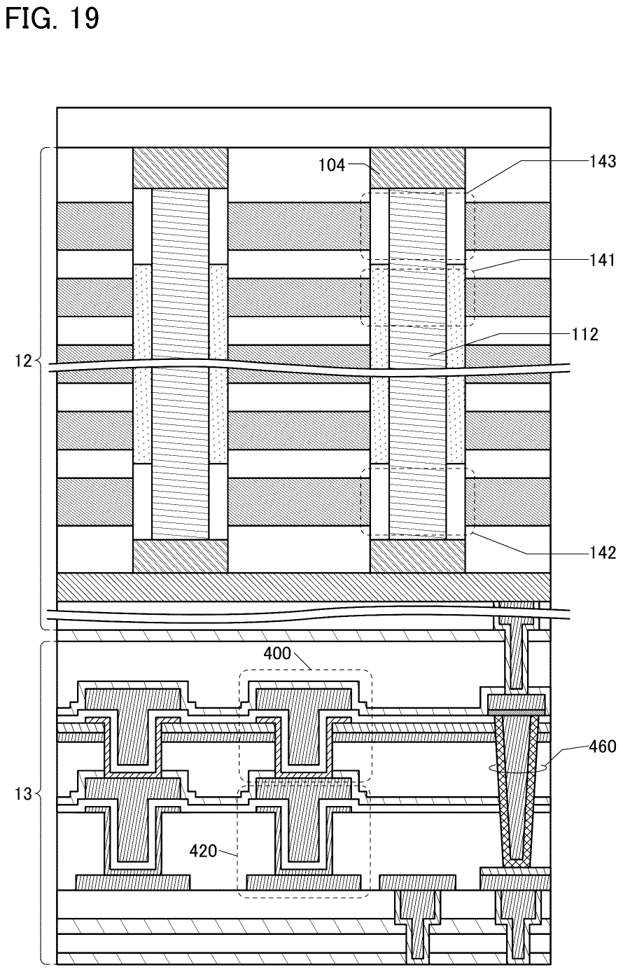

Note that although the structure where the layer 13 is provided over the layer 12 is illustrated above, a structure where the layer 12 is provided over the layer 13 may be employed. For example, FIG. 17 illustrates an example where the layer 13 including the transistor 200 is placed below the layer 12. In addition, FIG. 18 illustrates an example where the layer 13 including the transistor 400a and the transistor 400b is placed below the layer 12. FIG. 17 and FIG. 18 each illustrate an example where the layer 13 includes a conductive layer 260 and a conductive layer 460 each functioning as a plug. The layer 11 (not illustrated) that is placed on the lower side than the layer 13 can be connected to the layer 12 over the layer 13 with the conductive layer 260 or the conductive layer 460 therebetween. Furthermore, FIG. 19 illustrates an example where the layer 13 including the transistor 400 and the capacitor 420 is placed below the layer 12.

At least part of the structure examples, the drawings corresponding thereto, and the like described in this embodiment can be combined with the other structure examples, the other drawings, and the like as appropriate.

### Embodiment 3

In this embodiment, a semiconductor device 900 according to one embodiment of the present invention, which is different from the above embodiment, will be described. The semiconductor device 900 can function as a storage device. A semiconductor device where the memory cell portion MCL or the memory cell portion OMCL illustrated in Embodiment 1 can be employed will be described below.

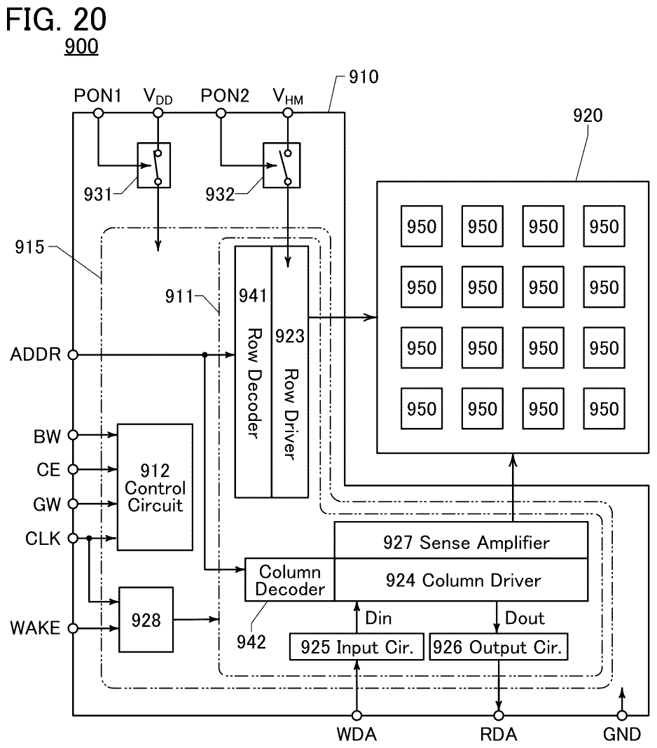

FIG. 20 is a block diagram illustrating a structure example of the semiconductor device 900. The semiconductor device 900 illustrated in FIG. 20 includes a driver circuit 910 and a memory array 920. The memory array 920 includes one or more memory cells 950. FIG. 20 illustrates an example where the memory array 920 includes a plurality of memory cells 950 arranged in a matrix.

The memory cell portion MCL, the memory cell portion OMCL, or the like illustrated in the above embodiment can be employed for the memory cell 950.

The driver circuit 910 includes a PSW 931 (a power switch), a PSW 932, and a peripheral circuit 915. The peripheral circuit 915 includes a peripheral circuit 911, a control circuit 912 (Control Circuit), and a voltage generation circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating a negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for writing and reading data to/from the memory cell 950. The peripheral circuit 911 includes a row decoder 941 (Row Decoder), a column decoder 942 (Column Decoder), a row driver 923 (Row Driver), a column driver 924 (Column Driver), an input circuit 925 (Input Cir.), an output circuit 926 (Output Cir.), and a sense amplifier 927 (Sense Amplifier).

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting a row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained by the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of VDD to the peripheral circuit 915. The PSW 932 has a function of controlling the supply of VHM to the row driver 923. Here, in the semiconductor device 900, a high power supply voltage is VDD and a low power supply voltage is GND (a ground potential). In addition, VHM is a high power supply voltage used to set a word line at a high level and is higher than VDD. The ON/OFF of the PSW 932 is controlled by the signal PON1, and the ON/OFF of the PSW 932 is controlled by the signal PON2. The number of power domains to which VDD is supplied is one in the peripheral circuit 915 in FIG. 20 but can be more than one. In that case, a power switch is provided for each power domain.

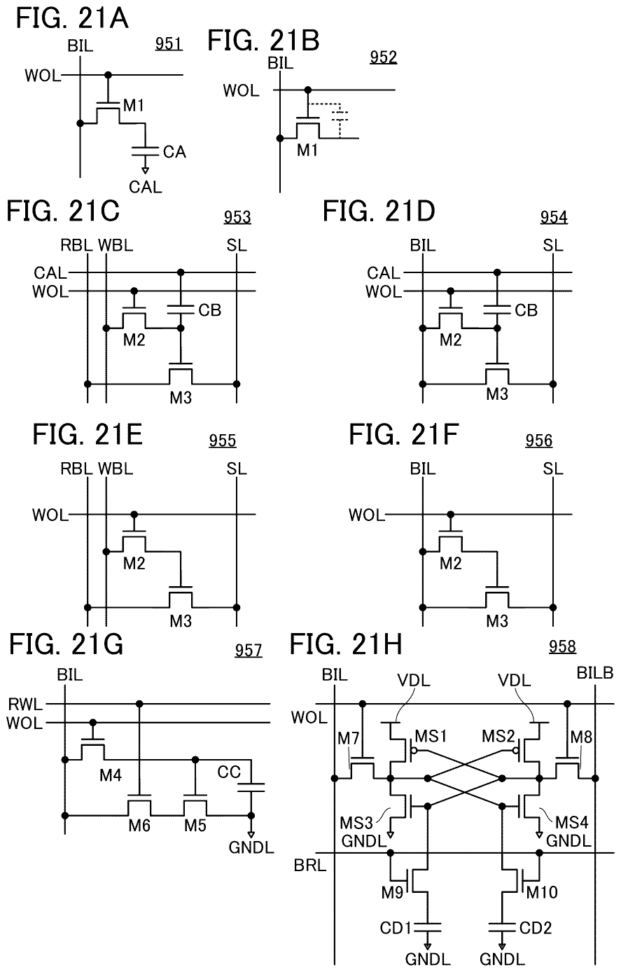

Structure examples of other memory cells that can be employed as the memory cell 950 are described using FIG. 21A to FIG. 21H.

Note that in the following description, the expression “two components are connected” includes the case where the two components are electrically connected through a circuit element (a transistor, a switch, a diode, a resistor, or the like). Electrical connection refers to a state where current can flow between two components. Note that the case where two components are connected through a switch or a transistor is also included as electrical connection because current can flow when the components are in an on state.

### DOSRAM

FIG. 21A illustrates a circuit structure example of a DRAM memory cell. In this specification and the like, a DRAM using an OS transistor is referred to as a DOSRAM (Dynamic Oxide Semiconductor Random Access Memory). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected.

A first terminal of the transistor M1 is connected to a first terminal of the capacitor CA. A second terminal of the transistor M1 is connected to a wiring BIL. A gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In data writing and reading, a low-level potential (referred to as a reference potential in some cases) is preferably applied to the wiring CAL.

Data writing and reading are performed in such a manner that a high-level potential is applied to the wiring WOL to turn on the transistor M1 so that the wiring BIL and the first terminal of the capacitor CA are brought into a conduction state (a state where current can flow therethrough).

The memory cell that can be used as the memory cell 950 is not limited to the memory cell 951, and the circuit structure can be changed. For example, the structure of a memory cell 952 illustrated in FIG. 21B may be employed. The memory cell 952 is an example including neither the capacitor CA nor the wiring CAL. The first terminal of the transistor M1 is in an electrically floating state.

In the memory cell 952, a potential written through the transistor MI is retained in a capacitor (also referred to as parasitic capacitance) between the first terminal and the gate, which is shown by a dashed line. Such a structure enables significant simplification of the structure of the memory cell.

Note that an OS transistor is preferably used as the transistor M1. An OS transistor has a characteristic of extremely low off-state current. The use of an OS transistor as the transistor M1 enables the leakage current of the transistor MI to be extremely low. That is, written data can be retained for a long time with the transistor M1, and thus the frequency of refresh of the memory cell can be decreased. Alternatively, refresh operation of the memory cell can be unnecessary. In addition, the extremely low leakage current allows multi-level data or analog data to be retained in the memory cell 951 and the memory cell 952.

### NOSRAM

FIG. 21C illustrates a circuit structure example of a gain-cell-type memory cell including two transistors and one capacitor. A memory cell 953 includes a transistor M2, a transistor M3, and a capacitor CB. In this specification and the like, a storage device including a gain-cell-type memory cell using an OS transistor as the transistor M2 is referred to as a NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In data writing, during data retention, and in data reading, a low-level potential (referred to as a reference potential in some cases) is preferably applied to the wiring CAL.

Data writing is performed in such a manner that a high-level potential is applied to the wiring WOL to turn on the transistor M2 so that the wiring WBL and the first terminal of the capacitor CB are brought into a conduction state. Specifically, when the transistor M2 is in an on state, a potential corresponding to information to be stored is applied to the wiring WBL, and the potential is written to the first terminal of the capacitor CB and the gate of the transistor M3. Then, a low-level potential is applied to the wiring WOL to turn off the transistor M2 so that the potential of the first terminal of the capacitor CB and the potential of the gate of the transistor M3 are retained.

Data reading is performed by applying a predetermined potential to the wiring SL. Current flowing between a source and a drain of the transistor M3 and the potential of the first terminal of the transistor M3 are determined by the potential of the gate of the transistor M3 and the potential of the second terminal of the transistor M3; thus, by reading the potential of the wiring RBL connected to the first terminal of the transistor M3, the potential retained in the first terminal of the capacitor CB (or the gate of the transistor M3) can be read. In other words, information written to this memory cell can be read from the potential retained in the first terminal of the capacitor CB (or the gate of the transistor M3).

Alternatively, for example, the wiring WBL and the wiring RBL may be combined into one wiring BIL. FIG. 21D illustrates a circuit structure example of the memory cell. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

A memory cell 955 illustrated in FIG. 21E is an example where the capacitor CB and the wiring CAL in the memory cell 953 are omitted. A memory cell 956 illustrated in FIG. 21F is an example where the capacitor CB and the wiring CAL in the memory cell 954 are omitted. With such structures, the degree of integration of memory cells can be increased.

Note that an OS transistor is preferably used as at least the transistor M2. In particular, an OS transistor is preferably used as each of the transistor M2 and the transistor M3.

Since the OS transistor has a characteristic of extremely low off-state current, written data can be retained for a long time with the transistor M2, and thus the frequency of refresh of the memory cell can be decreased. Alternatively, refresh operation of the memory cell can be unnecessary. In addition, the extremely low leakage current allows multi-level data or analog data to be retained in the memory cell 953, the memory cell 954, the memory cell 955, and the memory cell 956.

The memory cell 953, the memory cell 954, the memory cell 955, and the memory cell 956 each employing the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

In the case where an OS transistor is used as the transistor M3, the memory cell can be configured with only n-type transistors.

FIG. 21G illustrates a gain-cell-type memory cell 957 including three transistors and one capacitor. The memory cell 957 includes a transistor M4 to a transistor M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6, and a gate of the transistor M5 is connected to the first terminal of the capacitor CC. A second terminal of the transistor M6 is connected to the wiring BIL, and a gate of the transistor M6 is connected to a wiring RWL.

The wiring BIL functions as a bit line, the wiring WOL functions as a write word line, and the wiring RWL functions as a read word line. The wiring GNDL is a wiring for applying a low-level potential.

Data writing is performed in such a manner that a high-level potential is applied to the wiring WOL to turn on the transistor M4 so that the wiring BIL and the first terminal of the capacitor CC are brought into a conduction state. Specifically, when the transistor M4 is in an on state, a potential corresponding to information to be stored is applied to the wiring BIL, and the potential is written to the first terminal of the capacitor CC and the gate of the transistor M5. Then, a low-level potential is applied to the wiring WOL to turn off the transistor M4 so that the potential of the first terminal of the capacitor CC and the potential of the gate of the transistor M5 are retained.

Data reading is performed in such a manner that after a predetermined potential is precharged to the wiring BIL, the wiring BIL is brought into an electrically floating state, and a high-level potential is applied to the wiring RWL. Since the wiring RWL has the high-level potential, the transistor M6 is turned on, and the wiring BIL and the second terminal of the transistor M5 are brought into a conduction state. At this time, the potential of the wiring BIL is applied to the second terminal of the transistor M5; however, the potential of the second terminal of the transistor M5 and the potential of the wiring BIL are changed in accordance with the potential retained in the first terminal of the capacitor CC (or the gate of the transistor M5). Here, by reading the potential of the wiring BIL, the potential retained in the first terminal of the capacitor CC (or the gate of the transistor M5) can be read. In other words, information written to the memory cell can be read from the potential retained in the first terminal of the capacitor CC (or the gate of the transistor M5).

Note that an OS transistor is preferably used as at least the transistor M4.

Note that a Si transistor may be used as each of the transistors M5 and M6. As described above, a Si transistor has higher field-effect mobility than an OS transistor in some cases depending on the crystal state of silicon used in a semiconductor layer, for example.

In the case where an OS transistor is used as each of the transistors M5 and M6, the memory cell can be configured with only n-type transistors.

### OS-SRAM

FIG. 21H illustrates an example of an SRAM (Static Random Access Memory) using an OS transistor. In this specification and the like, an SRAM using an OS transistor is referred to as an OS-SRAM (Oxide Semiconductor-SRAM). Note that a memory cell 958 illustrated in FIG. 21H is a memory cell of an SRAM capable of backup.

The memory cell 958 includes a transistor M7 to a transistor M10, a transistor MS1 to a transistor MS4, a capacitor CD1, and a capacitor CD2. Note that the transistor MS1 and the transistor MS2 are p-channel transistors, and the transistor MS3 and the transistor MS4 are n-channel transistors.

A first terminal of the transistor M7 is connected to the wiring BIL, and a second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB, and a second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1, and a gate of the transistor M9 is connected to the wiring BRL. A second terminal of the transistor M10 is connected to a first terminal of the capacitor CD2, and a gate of the transistor M10 is connected to the wiring BRL.

A second terminal of the capacitor CD1 is connected to the wiring GNDL, and a second terminal of the capacitor CD2 is connected to the wiring GNDL.

The wiring BIL and the wiring BILB each function as a bit line, the wiring WOL functions as a word line, and the wiring BRL is a wiring that controls the on state and off state of each of the transistor M9 and the transistor M10.

The wiring VDL is a wiring for applying a high-level potential, and the wiring GNDL is a wiring for applying a low-level potential.

Data writing is performed by applying a high-level potential to the wiring WOL and applying a high-level potential to the wiring BRL. Specifically, when the transistor M10 is in an on state, a potential corresponding to information to be stored is applied to the wiring BIL, and the potential is written to a second terminal side of the transistor M10.

In the memory cell 958, an inverter loop is constructed by the transistor MS1 to the transistor MS2; thus, an inverted signal of a data signal corresponding to the potential is input to the second terminal side of the transistor M8. Since the transistor M8 is in an on state, an inverted signal of the potential applied to the wiring BIL, that is, the signal input to the wiring BIL is output to the wiring BILB. Since the transistor M9 and the transistor M10 are in an on state, the potential of the second terminal of the transistor M7 and the potential of the second terminal of the transistor M8 are retained in the first terminal of the capacitor CD2 and the first terminal of the capacitor CD1, respectively. Then, a low-level potential is applied to the wiring WOL and a low-level potential is applied to the wiring BRL to turn on the transistor M7 to the transistor M10 so that the potential of the first terminal of the capacitor CD1 and the potential of the first terminal of the capacitor CD2 are retained.

Data reading is performed in such a manner that after a predetermined potential is precharged to the wiring BIL and the wiring BILB in advance, a high-level potential is applied to the wiring WOL and a high-level potential is applied to the wiring BRL so that the potential of the first terminal of the capacitor CD1 is refreshed by the inverter loop in the memory cell 958 and is output to the wiring BILB. Moreover, the potential of the first terminal of the capacitor CD2 is refreshed by the inverter loop in the memory cell 958 and is output to the wiring BIL. Since the potentials of the wiring BIL and the wiring BILB are changed from the precharged potentials to the potential of the first terminal of the capacitor CD2 and the potential of the first terminal of the capacitor CD1, respectively, the potential retained in the memory cell can be read from the potential of the wiring BIL or the wiring BILB.

Note that an OS transistor is preferably employed as each of the transistor M7 to the transistor M10. Accordingly, written data can be retained for a long time by the transistor M7 to the transistor M10; thus, the frequency of refresh of the memory cell can be reduced. Alternatively, refresh operation of the memory cell can be unnecessary.

Note that a Si transistor may be used as each of the transistor MS1 to the transistor MS4.

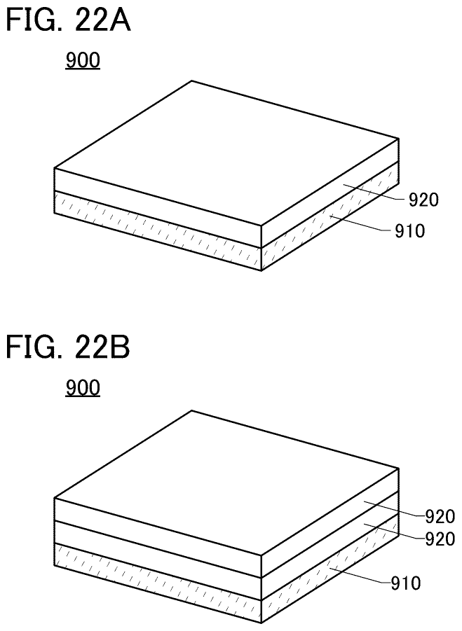

The driver circuit 910 and the memory array 920 that are included in the semiconductor device 900 may be provided on the same plane. As illustrated in FIG. 22A, the driver circuit 910 and the memory array 920 may be provided to overlap each other. When the driver circuit 910 and the memory array 920 are provided to overlap each other, the signal transmission distance can be shortened. Alternatively, as illustrated in FIG. 22B, a plurality of memory arrays 920 may be provided over the driver circuit 910.

Next, an example of an arithmetic processing unit that can include the semiconductor device such as the storage device described above.

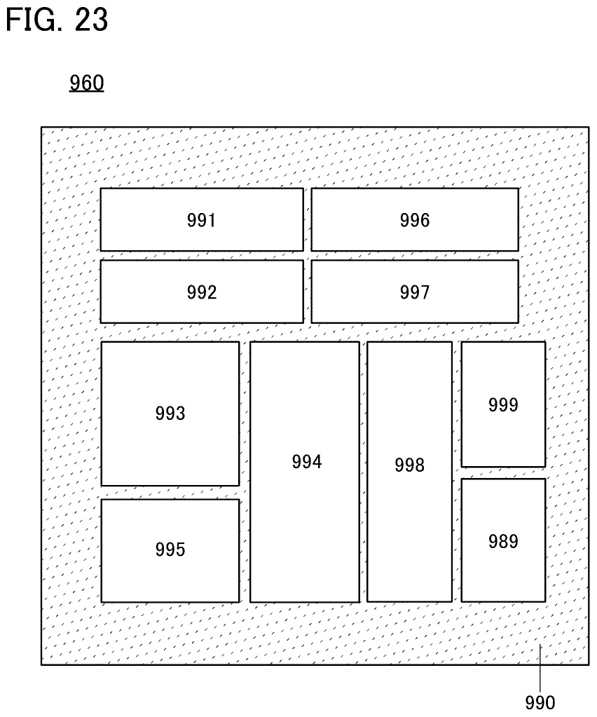

FIG. 23 illustrates a block diagram of an arithmetic unit 960. The arithmetic unit 960 illustrated in FIG. 23 can be employed as a CPU (Central Processing Unit), for example. The arithmetic unit 960 can also be employed as a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic unit 960 illustrated in FIG. 23 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic unit 960 may include a rewritable ROM and a ROM interface. In addition, the cache 999 and the cache interface 989 may be provided in a separate chip.

The cache 999 is connected to a main memory provided in a separate chip through the cache interface 989. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked and provided over the arithmetic unit 960. The memory array 920 can be used as a cache. In that case, the cache interface 989 may have a function of supplying data retained in the memory array 920 to the cache 999. Moreover, in that case, the driver circuit 910 is preferably included in part of the cache interface 989.

Note that it is also possible that the cache 999 is not provided and only the memory array 920 is used as a cache.

The arithmetic unit 960 illustrated in FIG. 23 is just an example with a simplified structure, and the actual arithmetic unit 960 has a variety of structures depending on the application. For example, what is called a multicore structure is preferably employed in which a plurality of cores each including the arithmetic unit 960 illustrated in FIG. 23 operate in parallel. The larger number of cores can increase arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic unit 960 can handle with an internal arithmetic circuit, a data bus, or the like can be 8 bits, 16 bits, 32 bits, 64 bits, or the like, for example.

An instruction that is input to the arithmetic unit 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct a variety of control in accordance with the decoded instruction. Specifically, the ALU controller 992 generates signals for controlling the operation of the ALU 991. While the arithmetic unit 960 is executing a program, the interrupt controller 994 judges an interrupt request from an external input/output device, a peripheral circuit, or the like on the basis of its priority, a mask state, or the like and processes the request. The register controller 997 generates an address of the register 996, and, for example, reads/writes data from/to the register 996 in accordance with the state of the arithmetic unit 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the variety of circuits described above.

In the arithmetic unit 960 illustrated in FIG. 23, the register controller 997 selects retention operation in the register 996 in accordance with an instruction from the ALU 991. That is, the register controller 997 selects whether data is retained by a flip-flop or data is retained by a capacitor in the memory cell included in the register 996. When data retention by the flip-flop is selected, a power supply voltage is supplied to the memory cell in the register 996. When data retention by the capacitor is selected, the data is rewritten to the capacitor, and the supply of a power supply voltage to the memory cell in the register 996 can be stopped.

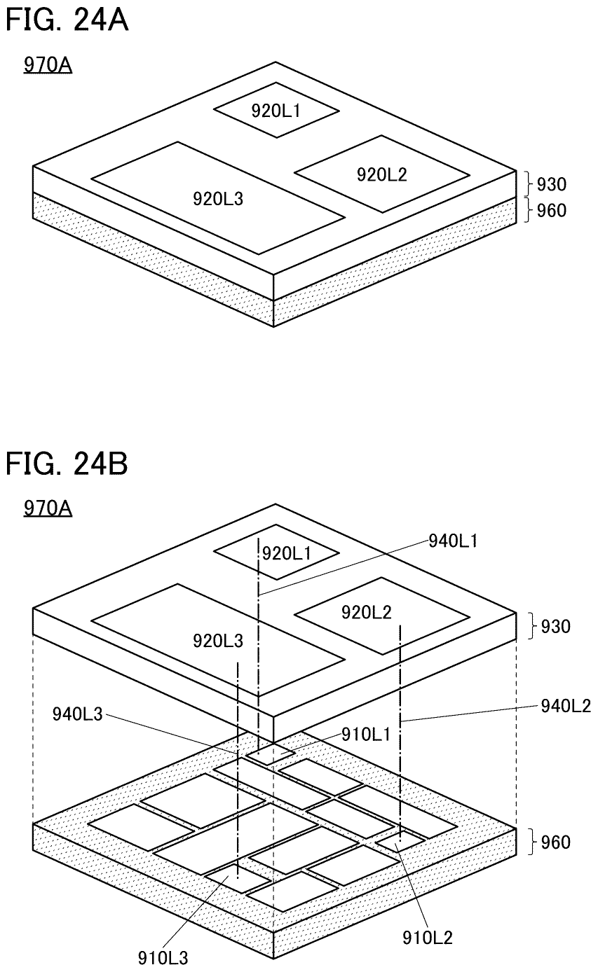

The memory array 920 and the arithmetic unit 960 can be provided to overlap each other. FIG. 24A and FIG. 24B illustrate perspective views of a semiconductor device 970A. The semiconductor device 970A includes a layer 930 provided with memory arrays over the arithmetic unit 960. A memory array 920L1, a memory array 920L2, and a memory array 920L3 are provided in the layer 930. The arithmetic unit 960 and the memory arrays have regions where they overlap each other. For easy understanding of the structure of the semiconductor device 970A, the arithmetic unit 960 and the layer 930 are separately illustrated in FIG. 24B.

Providing the arithmetic unit 960 and the layer 930 including the memory arrays to overlap each other can shorten the connection distance therebetween. Accordingly, communication speed therebetween can be increased. Moreover, since the connection distance is short, power consumption can be reduced.

As a method for stacking the layer 930 including the memory arrays and the arithmetic unit 960, either of the following methods may be employed: a method in which the layer 930 including the memory arrays is stacked directly on the arithmetic unit 960 (also referred to as monolithic stacking), and a method in which the arithmetic unit 960 and the layer 930 are formed over different substrates, the two substrates are attached to each other, and the arithmetic unit 960 and the layer 930 are connected with a through via or by a technique for bonding conductive films (Cu—Cu bonding or the like). The former method does not require consideration of misalignment in attachment; thus, not only chip size but also manufacturing cost can be reduced.

Here, it is possible that the arithmetic unit 960 does not include the cache 999 and the memory arrays 920L1, 920L2, and 920L3 provided in the layer 930 are each used as a cache. In that case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the largest capacity and the lowest access frequency. The memory array 920L 1 has the smallest capacity and the highest access frequency.

Note that in the case where the cache 999 provided in the arithmetic unit 960 is used as the L1 cache, the memory arrays provided in the layer 930 can each be used as a lower-level cache or a main memory. The main memory has larger capacity and lower access frequency than the cache.

As illustrated in FIG. 24B, a driver circuit 910L1, a driver circuit 910L2, and a driver circuit 910L3 are provided. The driver circuit 910L 1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or may be connected thereto.

Whether the memory array 920 functions as the cache or functions as the main memory is determined by the control circuit 912 included in each of the driver circuits 910. The control circuit 912 can make some of the plurality of memory cells 950 included in the semiconductor device 900 each function as a RAM in accordance with a signal supplied from the arithmetic unit 960.

In the semiconductor device 900, some of the plurality of memory cells 950 can each function as the cache and the other memory cells can each function as the main memory. That is, the semiconductor device 900 can have both the function of the cache and the function of the main memory. The semiconductor device 900 according to one embodiment of the present invention can function as a universal memory, for example.

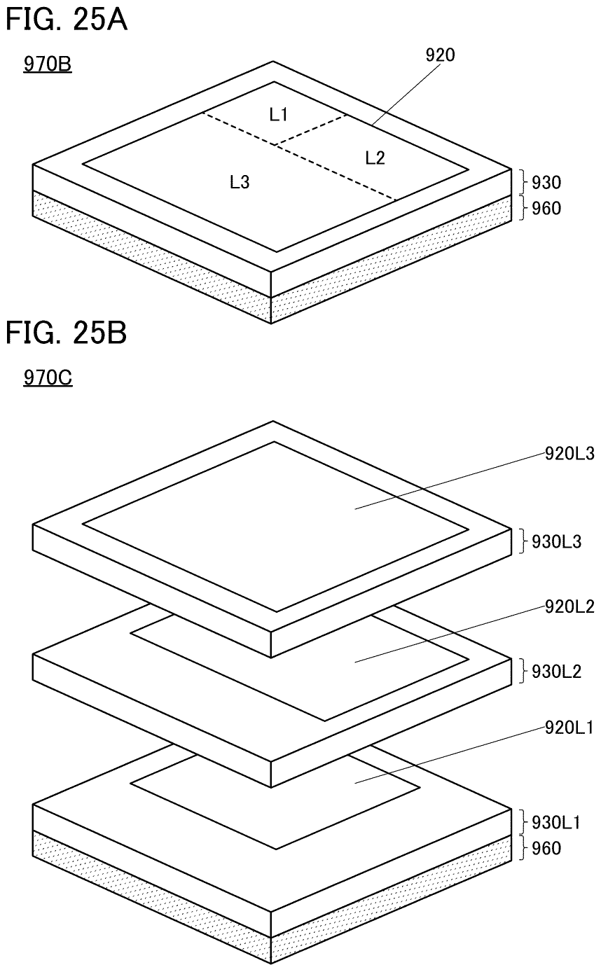

The layer 930 including one memory array 920 may be provided to overlap the arithmetic unit 960. FIG. 25A illustrates a perspective view of a semiconductor device 970B.

In the semiconductor device 970B, one memory array 920 can be divided into a plurality of areas having different functions. FIG. 25A illustrates an example where a region L1, a region L2, and a region L3 are used as the L1 cache, the L2 cache, and the L3 cache, respectively.

In the semiconductor device 970B, the capacity of each of the region LI to the region L3 can be changed depending on circumstances. For example, when the capacity of the L1 cache is to be increased, the capacity can be increased by increasing the area of the region L1. With such a structure, arithmetic processing efficiency can be increased and processing speed can be improved.

Alternatively, a plurality of memory arrays may be stacked. FIG. 25B illustrates a perspective view of a semiconductor device 970C.

In the semiconductor device 970C, a layer 930L 1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic unit 960 can be used as a high-level cache, and the memory array 920L3 physically farthest from the arithmetic unit 960 can be used as a low-level cache or a main memory. Such a structure can increase the capacity of each memory array, which leads to higher processing capability.

At least part of the structure examples, the drawings corresponding thereto, and the like described in this embodiment can be combined with the other structure examples, the other drawings, and the like as appropriate.

### Embodiment 4

In this embodiment, application examples of the storage device according to one embodiment of the present invention will be described.

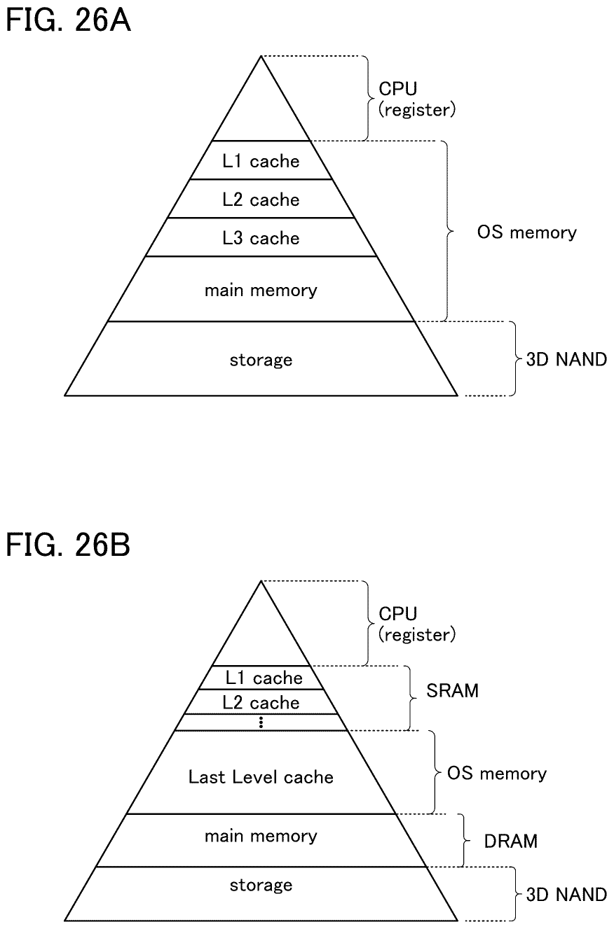

In general, a variety of storage devices are used in semiconductor devices such as computers depending on the intended use. FIG. 26A illustrates the hierarchy of a variety of storage devices used in a semiconductor device. The storage devices at the upper levels require higher operating speed, and the storage devices at the lower levels require larger memory capacity and higher memory density. In FIG. 26A, a memory integrated as a register in an arithmetic processing unit such as a CPU, an L1 cache, an L2 cache, an L3 cache, a main memory, a storage, and the like are provided in this order from the uppermost layer. Note that although the example where the caches up to the L3 cache are included is illustrated here, a lower-level cache may further be included.

A memory integrated as a register in an arithmetic processing unit such as a CPU is used for temporary storage of arithmetic operation results, for example, and thus is frequently accessed by the arithmetic processing unit. Accordingly, high operating speed is required rather than memory capacity. In addition, the register also has a function of retaining setting information of the arithmetic processing unit, for example.

The cache has a function of retaining the copy of part of data retained in a main memory. By duplicating data that is frequently used and retaining the copy of the data in the cache, the access speed to the data can be increased. The cache needs smaller memory capacity than the main memory but higher operating speed than the main memory. In addition, data that is rewritten in the cache is duplicated, and the duplicated data is supplied to the main memory.

The main memory has a function of retaining a program, data, and the like that are read from the storage.

The storage has a function of retaining data that needs to be retained for a long period and programs used in an arithmetic processing unit, for example. Therefore, the storage needs large memory capacity and high memory density rather than operating speed. For example, a high-capacity nonvolatile storage device such as a 3D NAND can be used.

Since the storage device according to one embodiment of the present invention includes a storage device with large memory capacity and a storage device with high operating speed, the storage device according to one embodiment of the present invention can be employed for both the layer where the storage is positioned and the layer where the main memory is positioned in FIG. 26A.

In addition, a storage device using an oxide semiconductor (an OS memory) according to one embodiment of the present invention operates at high speed and can retain data for a long period. Thus, as illustrated in FIG. 26A, the storage device according to one embodiment of the present invention can be suitably used for both the layers where the caches are positioned and the layer where the main memory is positioned.

FIG. 26B illustrates an example where an SRAM is employed as some of the caches and the OS memory according to one embodiment of the present invention is employed as the other cache.

The lowest-level cache can be referred to as a last level cache (LLC). The LLC does not require higher operating speed than a higher-level cache, but desirably has large memory capacity. The OS memory according to one embodiment of the present invention operates at high speed and can retain data for a long period, and thus can be suitably used as the LLC. Note that the OS memory according to one embodiment of the present invention can also be used as a final level cache (FLC).

For example, as illustrated in FIG. 26B, an SRAM can be used as each of the higher-level caches (the L1 cache, the L2 cache, and the like), and the OS memory according to one embodiment of the present invention can be used as the LLC. Moreover, a DRAM as well as the OS memory can be employed as the main memory, as illustrated in FIG. 26B.

At least part of the structure examples, the drawings corresponding thereto, and the like described in this embodiment can be combined with the other structure examples, the other drawings, and the like as appropriate.

### Embodiment 5

In this embodiment, application examples of the storage device according to one embodiment of the present invention will be described.

The storage device according to one embodiment of the present invention can be employed as storage devices of a variety of electronic devices (e.g., information terminals, computers, smartphones, e-book readers, digital still cameras, video cameras, video recording/reproducing devices, navigation systems, and game machines). The storage device can also be used for image sensors, IoT (Internet of Things), healthcare-related devices, and the like. Note that, here, the computers refer not only to tablet computers, laptop computers, and desktop computers but also to large computers such as server systems.

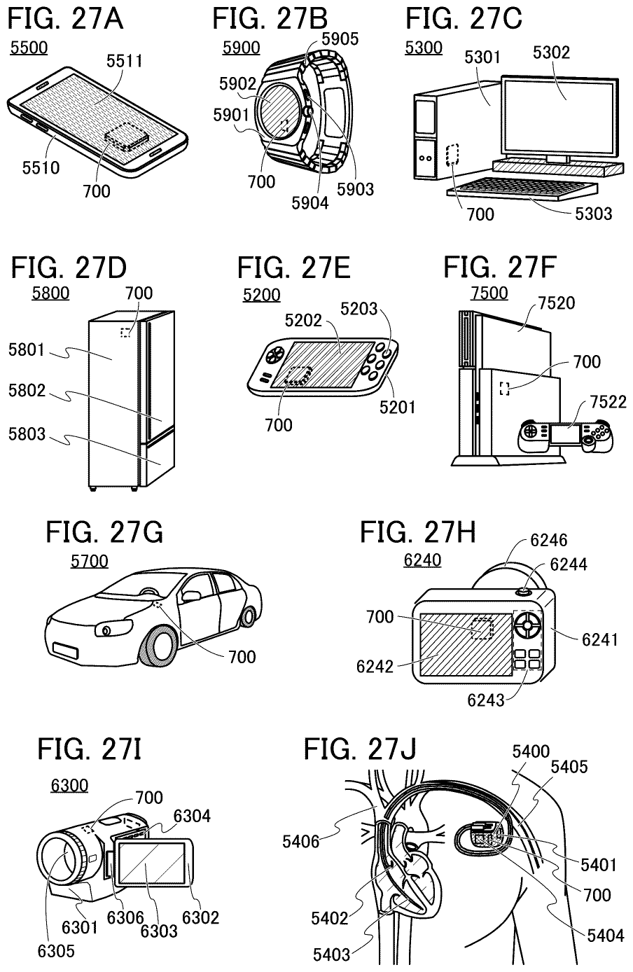

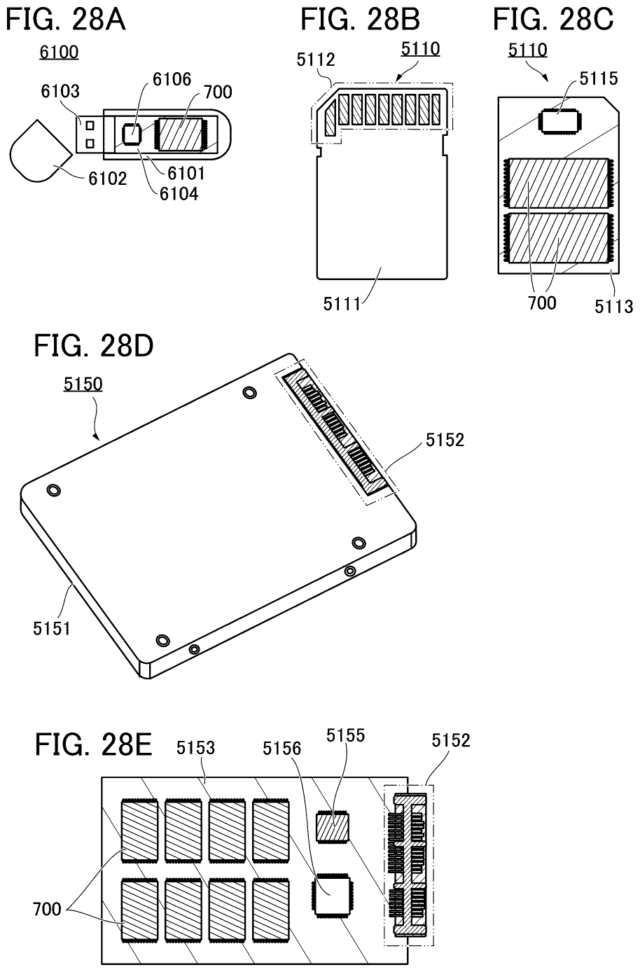

Examples of electronic devices including the storage device according to one embodiment of the present invention are described. Note that FIG. 27A to FIG. 27J and FIG. 28A to FIG. 28E each illustrate a state where the electronic component 700 including the storage device is included in each electronic device.

### Cellular Phone

An information terminal 5500 illustrated in FIG. 27A is a cellular phone (a smartphone), which is a kind of information terminal. The information terminal 5500 includes a housing 5510 and a display portion 5511, and as input interfaces, a touch panel is provided in the display portion 5511 and a button is provided in the housing 5510.

By employing the storage device according to one embodiment of the present invention, the information terminal 5500 can retain a temporary file generated at the time of executing an application (e.g., a web browser's cache).

### Wearable Terminal

FIG. 27B illustrates an information terminal 5900, which is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by employing the storage device according to one embodiment of the present invention.

### Information Terminal

FIG. 27C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by employing the storage device according to one embodiment of the present invention.

FIG. 27A to FIG. 27C illustrate the smartphone, the wearable terminal, and the desktop information terminal as electronic devices; other examples of information terminals include a PDA (Personal Digital Assistant), a laptop information terminal, and a workstation.

### Household Appliance

FIG. 27D illustrates an electric refrigerator-freezer 5800, which is an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The storage device according to one embodiment of the present invention can be employed for the electric refrigerator-freezer 5800. The electric refrigerator-freezer 5800 can transmit and receive information on food stored in the electric refrigerator-freezer 5800 and food expiration dates, for example, to and from an information terminal via the Internet. In the electric refrigerator-freezer 5800, the storage device according to one embodiment of the present invention can retain a temporary file generated at the time of transmitting the information.

FIG. 27D illustrates the electric refrigerator-freezer as a household appliance; other examples of household appliances include a vacuum cleaner, a microwave oven, an electric oven, a rice cooker, a water heater, an IH cooker, a water server, a heating and cooling appliance including an air conditioner, a washing machine, a drying machine, and an audio visual appliance.

### Game Machine

FIG. 27E illustrates a portable game machine 5200, which is an example of a game machine. The portable game machine 5200 includes a housing 5201, a display portion 5202, buttons 5203, and the like.

FIG. 27F illustrates a stationary game machine 7500, which is an example of a game machine. The stationary game machine 7500 can be particularly referred to as a home-use stationary game machine. The stationary game machine 7500 includes a main body 7520 and a controller 7522. Note that the controller 7522 can be connected to the main body 7520 with or without a wire. Although not illustrated in FIG. 27F, the controller 7522 can include a display portion that displays a game image, and an input interface besides the button, such as a touch panel, a stick, a rotating knob, and a sliding knob. Moreover, the shape of the controller 7522 is not limited to that illustrated in FIG. 27F, and the shape of the controller 7522 may be changed in various ways in accordance with the genres of games. For example, for a shooting game such as an FPS (First Person Shooter), a gun-shaped controller having a trigger button can be used. As another example, for a music game, a controller having a shape of a musical instrument, audio equipment, or the like can be used. Furthermore, the stationary game machine may be operated by a game player's gesture or voice without using a controller when the stationary game machine includes one or more of a camera, a depth sensor, and a microphone.

Video on the game machine can be output with a display device such as a television device, a personal computer display, a game display, or a head-mounted display.

By employing the storage device according to one embodiment of the present invention for the portable game machine 5200 or the stationary game machine 7500, power consumption can be reduced. Moreover, heat generation from a circuit can be reduced owing to the reduction in power consumption; thus, the influence of heat generation on the circuit itself, a peripheral circuit, and a module can be reduced.

Moreover, by employing the storage device according to one embodiment of the present invention for the portable game machine 5200 or the stationary game machine 7500, it is possible to retain a temporary file or the like necessary for arithmetic operation that occurs during game play.

FIG. 27E and FIG. 27F illustrate the portable game machine and the home-use stationary game machine as examples of game machines, and examples of other game machines include an arcade game machine installed in an entertainment facility (a game center, an amusement park, or the like) and a throwing machine for batting practice that is installed in a sports facility.

### Moving Vehicle

The storage device according to one embodiment of the present invention can be employed for a motor vehicle, which is a moving vehicle, and the periphery of a driver's seat in the motor vehicle.

FIG. 27G illustrates a motor vehicle 5700 as an example of a moving vehicle.

An instrument panel that provides a variety of information by displaying a speedometer, a tachometer, mileage, a fuel meter, a gearshift state, air-conditioning settings, and the like is provided around the driver's seat in the motor vehicle 5700. In addition, a display device showing the above information may be provided around the driver's seat.

In particular, the display device can compensate for the view obstructed by a pillar, for example, blind areas for the driver's seat, and the like by displaying video from an imaging device (not illustrated) provided for the motor vehicle 5700, which can increase safety. That is, display of an image from an imaging device provided on the outside of the motor vehicle 5700 can fill in blind areas and increase safety.

The storage device according to one embodiment of the present invention can temporarily retain information; thus, the storage device can be used to retain temporary information necessary in a system conducting autonomous driving, navigation, risk prediction, or the like for the motor vehicle 5700, for example. Moreover, the storage device according to one embodiment of the present invention may be configured to retain video of a driving recorder provided in the motor vehicle 5700.

Note that although the motor vehicle is described above as an example of a moving vehicle, the moving vehicle is not limited to the motor vehicle. Examples of the moving vehicle include a train, a monorail train, a ship, and a flying object (a helicopter, an unmanned aircraft (drone), an airplane, or a rocket).

### Camera

The storage device according to one embodiment of the present invention can be employed for a camera.

FIG. 27H illustrates a digital camera 6240, which is an example of an imaging device. The digital camera 6240 includes a housing 6241, a display portion 6242, operation switches 6243, a shutter button 6244, and the like, and a detachable lens 6246 is attached to the digital camera 6240. Note that, here, although the digital camera 6240 is configured such that the lens 6246 is detachable from the housing 6241 for replacement, the lens 6246 may be integrated with the housing 6241. Moreover, the digital camera 6240 may be configured to be additionally equipped with a stroboscope, a viewfinder, or the like.

By employing the storage device according to one embodiment of the present invention for the digital camera 6240, power consumption can be reduced. Moreover, heat generation from a circuit can be reduced owing to the reduction in power consumption; thus, the influence of heat generation on the circuit itself, a peripheral circuit, and a module can be reduced.

### Video Camera

The storage device according to one embodiment of the present invention can be employed for a video camera.

FIG. 27I illustrates a video camera 6300, which is an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Video on the display portion 6303 may be switched in accordance with the angle at the joint 6306 between the first housing 6301 and the second housing 6302.

When video taken by the video camera 6300 is recorded, the video needs to be encoded in accordance with a data recording format. By using the storage device according to one embodiment of the present invention, the video camera 6300 can retain a temporary file generated at the time of encoding.

### ICD

The storage device according to one embodiment of the present invention can be employed for an implantable cardioverter-defibrillator (ICD).

FIG. 27J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 has a function of a pacemaker and paces the heart when the heart rate is out of a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for sensing the heart rate. In the ICD main unit 5400, data on the heart rate obtained by the sensor, the number of times treatment with pacing is performed, and the time taken for the treatment, for example, can be stored in the electronic component 700.

In addition, the antenna 5404 can receive electric power, and the battery 5401 is charged with the electric power. Furthermore, when the ICD main unit 5400 includes a plurality of batteries, safety can be increased. Specifically, even when some of the batteries in the ICD main unit 5400 run out, the other batteries can function; thus, the batteries also function as an auxiliary power source.

In addition to the antenna 5404 that can receive electric power, an antenna that can transmit a physiological signal may be included to construct, for example, a system that monitors cardiac activity by checking physiological signals such as a pulse, a respiratory rate, a heart rate, and body temperature with an external monitoring device.

### Expansion Device for PC

The storage device according to one embodiment of the present invention can be employed for a computer such as a PC (Personal Computer) and an expansion device for an information terminal.

FIG. 28A illustrates, as an example of the expansion device, a portable expansion device 6100 that includes a chip capable of retaining information and is externally provided on a PC. The expansion device 6100 can store information using the chip when connected to a PC with a USB (Universal Serial Bus), for example. Note that FIG. 28A illustrates the portable expansion device 6100; however, the expansion device according to one embodiment of the present invention is not limited thereto and may be a comparatively large expansion device incorporating a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the storage device according to one embodiment of the present invention, for example. For example, the electronic component 700 and a controller chip 6106 are attached to the substrate 6104. The USB connector 6103 functions as an interface for connection to an external device.

### SD Card

The storage device according to one embodiment of the present invention can be employed for an SD card that can be attached to an electronic device such as an information terminal or a digital camera.

FIG. 28B is a schematic external diagram of an SD card, and FIG. 28C is a schematic diagram of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a storage device and a circuit for driving the storage device. For example, the electronic components 700 and a controller chip 5115 are attached to the substrate 5113. Note that the circuit structures of the electronic components 700 and the controller chip 5115 are not limited to those described above, and may be changed as appropriate according to circumstances. For example, a write circuit, a row driver, a read circuit, or the like provided in an electronic component may be incorporated in the controller chip 5115 instead of the electronic component 700.

When the electronic components 700 are provided also on a rear surface side of the substrate 5113, the capacity of the SD card 5110 can be increased. In addition, a wireless chip with a wireless communication function may be provided on the substrate 5113. This allows wireless communication between an external device and the SD card 5110 and enables data reading and writing from and to the electronic components 700.

### SSD

The storage device according to one embodiment of the present invention can be employed for an SSD (Solid State Drive) that can be attached to an electronic device such as an information terminal.

FIG. 28D is a schematic external diagram of an SSD, and FIG. 28E is a schematic diagram of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a storage device and a circuit for driving the storage device. For example, the electronic components 700, a memory chip 5155, and a controller chip 5156 are attached to the substrate 5153. When the electronic components 700 are also provided on a rear surface side of the substrate 5153, the capacity of the SSD 5150 can be increased. A work memory is incorporated in the memory chip 5155. For example, a DRAM chip is used as the memory chip 5155. A processor, an ECC (Error-Correcting Code) circuit, and the like are incorporated in the controller chip 5156. Note that the circuit structures of the electronic components 700, the memory chip 5155, and the controller chip 5115 are not limited to those described above, and may be changed as appropriate according to circumstances. For example, a memory functioning as a work memory may also be provided in the controller chip 5156.

### Computer

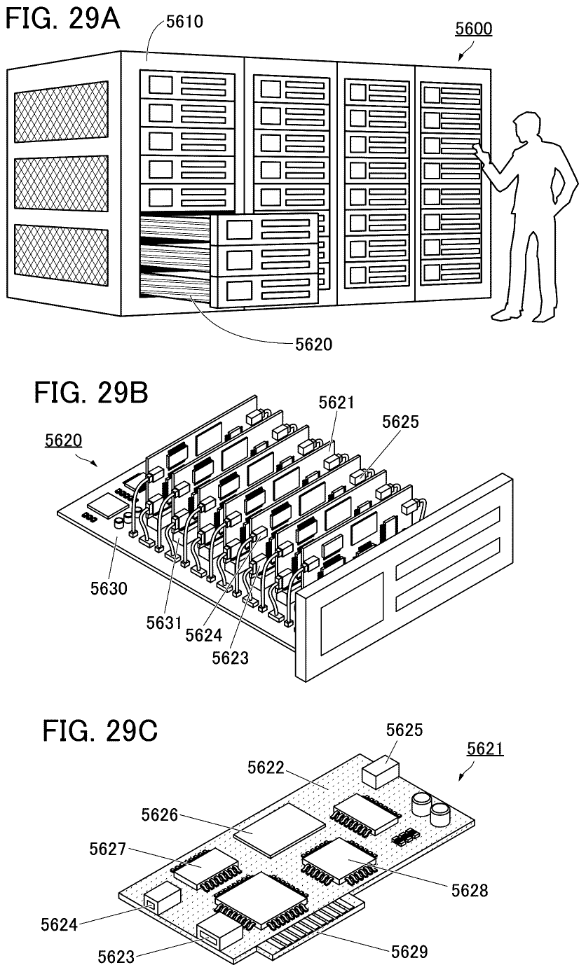

A computer 5600 illustrated in FIG. 29A is an example of a large computer. In the computer 5600, a plurality of rack mount computers 5620 are stored in a rack 5610.

The computer 5620 can have a structure in a perspective view illustrated in FIG. 29B, for example. In FIG. 29B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 29C is an example of a processing board provided with a CPU, a GPU, a storage device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 29C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The storage device according to one embodiment of the present invention is used in a variety of electronic devices and the like described above, so that a reduction in size and a reduction in power consumption of the electronic devices can be achieved. In addition, since the storage device according to one embodiment of the present invention has low power consumption, heat generation from a circuit can be reduced. Accordingly, it is possible to reduce adverse effects of the heat generation on the circuit itself, a peripheral circuit, and a module. Furthermore, the use of the storage device according to one embodiment of the present invention can achieve an electronic device that stably operates even in a high temperature environment. Thus, the reliability of the electronic device can be increased.

At least part of the structure examples, the drawings corresponding thereto, and the like described in this embodiment can be combined with the other structure examples, the other drawings, and the like as appropriate.

### Embodiment 6

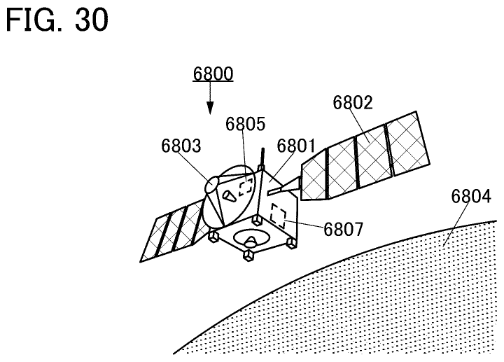

In this embodiment, a specific example of the case where the semiconductor device according to one embodiment of the present invention is employed for a device for space will be described using FIG. 30.

The semiconductor device according to one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space.

FIG. 30 illustrates an artificial satellite 6800 as an example of a device for space. The artificial satellite 6800 includes a body 6801, a solar panel 6802, an antenna 6803, a secondary battery 6805, and a control device 6807. Note that in FIG. 30, a planet 6804 in outer space is illustrated as an example. Note that outer space refers to, for example, space at an altitude greater than or equal to 100 km, and outer space described in this specification may include one or more of thermosphere, mesosphere, and stratosphere.

In addition, the amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, meson beams, and the like.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed using one or more selected from a CPU, a GPU, and a storage device, for example. Note that the semiconductor device including the OS transistor, which is one embodiment of the present invention, is suitably used for the control device 6807. A change in electrical characteristics due to exposure to radiation is smaller in the OS transistor than in a Si transistor. That is, the OS transistor has high reliability and thus can be suitably used even in an environment where radiation can enter.

Alternatively, the artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Note that although the artificial satellite is described as an example of a device for space in this embodiment, the present invention is not limited thereto. The semiconductor device according to one embodiment of the present invention can be suitably used for a device for space, such as a spacecraft, a space capsule, or a space probe, for example.

At least part of the structure examples, the drawings corresponding thereto, and the like described in this embodiment can be combined with the other structure examples, the other drawings, and the like as appropriate.

### REFERENCE NUMERALS

10: semiconductor device, 11: layer, 12: layer, 13: layer, 21: storage device, 22: terminal portion, 23: plug, 31: storage device, 32: connection portion, 33: plug, 42: driver circuit, 43: driver circuit, 45: wiring, 50: insulating layer, 51: conductive layer, 52: conductive layer, 53: conductive layer, 54: conductive layer, 55: conductive layer, 56: plug, 57: conductive layer, 60: memory string, 65: memory cell, 71: curve, 72: curve, 100A: memory string, 100: memory string, 101: conductive layer, 102_1: insulating layer, 102_m: insulating layer, 102: insulating layer, 103_1: conductive layer, 103_n: conductive layer, 103: conductive layer, 104: conductive layer, 105: insulating layer, 106: conductive layer, 110: structural body, 111: insulating layer, 112: semiconductor layer, 118: functional layer, 120: central axis, 121: insulating layer, 122: insulating layer, 125: conductive layer, 126: conductive layer, 127: conductive layer, 131: insulating layer, 132: insulating layer, 133: insulating layer, 141: transistor, 142: transistor, 143: transistor, 200: transistor, 201: semiconductor layer, 202: conductive layer, 203: insulating layer, 204: conductive layer, 205: conductive layer, 210: insulating layer, 212: insulating layer, 214: insulating layer, 216: insulating layer, 218: conductive layer, 220: insulating layer, 222: insulating layer, 224: insulating layer, 234: insulating layer, 236: conductive layer, 238: conductive layer, 240: insulating layer, 241: insulating layer, 242: insulating layer, 244: insulating layer, 246: insulating layer, 248: insulating layer, 250: capacitor, 251: conductive layer, 252: conductive layer, 253: insulating layer, 254: conductive layer, 300: transistor, 311: substrate, 313: semiconductor region, 314a: low-resistance region, 314b: low-resistance region, 315: insulating layer, 316: conductive layer, 320: insulating layer, 322: insulating layer, 324: insulating layer, 326: insulating layer, 328: conductive layer, 330: conductive layer, 350: insulating layer, 384: insulating layer, 386: conductive layer, 400a: transistor, 400b: transistor, 400: transistor, 401: semiconductor layer, 402: conductive layer, 403: insulating layer, 404: conductive layer, 405: conductive layer, 406: conductive layer, 407: conductive layer, 410: insulating layer, 412: insulating layer, 414: insulating layer, 416: insulating layer, 418: insulating layer, 420: capacitor, 421: conductive layer, 422: conductive layer, and 423: insulating layer.

1. A semiconductor device comprising:
a first layer, a second layer, and a third layer,
wherein the first layer comprises a first storage device where a plurality of nonvolatile first storage elements are stacked in a thickness direction of the first layer,
wherein the second layer comprises a second storage device comprising a plurality of second storage elements,
wherein each of the plurality of second storage elements comprises a first transistor comprising an oxide semiconductor in a channel formation region,
wherein the third layer comprises a first driver circuit configured to control operation of the first storage device and a second driver circuit configured to control operation of the second storage device, and
wherein the first layer and the second layer overlap each other, the second layer and the third layer overlap each other, and the first layer and the third layer overlap each other.

2. The semiconductor device according to claim 1,
wherein the first layer is positioned over the third layer, and
wherein the second layer is positioned over the third layer.

3. The semiconductor device according to claim 1,
wherein the third layer is positioned between the first layer and the second layer.

4. The semiconductor device according to claim 1,
wherein each of the plurality of nonvolatile first storage elements comprises a first conductive layer, a first semiconductor layer, and a functional layer between the first conductive layer and the first semiconductor layer, and
wherein the functional layer comprises a thin film exhibiting ferroelectricity.

5.

5. The semiconductor device according to claim 1,
wherein each of the plurality of nonvolatile first storage elements comprises a first conductive layer, a first semiconductor layer, and a functional layer between the first conductive layer and the first semiconductor layer, and
wherein the functional layer comprises at least one of hafnium and zirconium.

6. The semiconductor device according to claim 5,
wherein the functional layer further comprises one or more of scandium, yttrium, and a lanthanoid.

7. The semiconductor device according to claim 1,
wherein the first transistor comprises a gate insulating layer, and
wherein the gate insulating layer comprises a thin film exhibiting ferroelectricity.

8. The semiconductor device according to claim 1,
wherein the second layer comprises an insulating layer,
wherein the first transistor comprises a source electrode, a drain electrode, and a second semiconductor layer,
wherein each of the source electrode and the drain electrode is in contact with the second semiconductor layer,
wherein one of the source electrode and the drain electrode is positioned above the insulating layer, and
wherein the other of the source electrode and the drain electrode is positioned below the insulating layer.

9. A semiconductor device comprising:
a first layer, a second layer, and a third layer,
wherein the first layer comprises a first storage device comprising a plurality of nonvolatile first storage elements,
wherein a second nonvolatile first storage element of the plurality of nonvolatile first storage elements is provided over a first nonvolatile first storage element of the plurality of nonvolatile first storage elements,
wherein the second layer comprises a second storage device comprising a plurality of second storage elements,
wherein one of the plurality of second storage elements comprises a first transistor comprising an oxide semiconductor in a channel formation region,
wherein the third layer comprises a first driver circuit configured to control operation of the first storage device and a second driver circuit configured to control operation of the second storage device, and
wherein the first layer and the second layer overlap each other, the second layer and the third layer overlap each other, and the first layer and the third layer overlap each other.

10. A semiconductor device comprising:
a first layer, a second layer, and a third layer,
wherein the first layer comprises a first storage device comprising a plurality of nonvolatile first storage elements,
wherein a second nonvolatile first storage element of the plurality of nonvolatile first storage elements is provided over a first nonvolatile first storage element of the plurality of nonvolatile first storage elements,
wherein the second layer comprises a second storage device comprising a plurality of second storage elements,
wherein one of the plurality of second storage elements comprises a first transistor comprising an oxide semiconductor in a channel formation region,
wherein the third layer comprises a first driver circuit configured to control operation of the first storage device and a second driver circuit configured to control operation of the second storage device,
wherein the first transistor comprises a gate insulating layer,
wherein the gate insulating layer comprises a thin film exhibiting ferroelectricity,
wherein one of the plurality of nonvolatile first storage elements comprises a first conductive layer, a first semiconductor layer, and a functional layer between the first conductive layer and the first semiconductor layer, and
wherein the functional layer comprises a thin film exhibiting ferroelectricity.
